(19) United States
(12) Patent Application Publication
(10) Pub. No.: US 2014/0326302 A1
(43) Pub. Date: Nov. 6, 2014

(54) SOLAR CELL

(71) Applicants: Sharp Kabushiki Kaisha, Osaka-shi, Osaka (JP); The University of Tokyo, Bunkyo-ku, Tokyo (JP)

(72) Inventors: Yasuhiko Arakawa, Bunkyo-ku (JP); Tomohiro Nozawa, Osaka-shi (JP); Makoto Izumi, Osaka-shi (JP)

(21) Appl. No.: 14/352,846

(22) PCT Filed: Sep. 20, 2012
(86) PCT No.: PCT/JP2012/074072

§ 371 Date: Apr. 18, 2014

(30) Foreign Application Priority Data
Oct. 20, 2011 (JP) 2011-230782

(51) Int. Cl. H01L 31/0352

(52) U.S. Cl. CPC H01L 31/035218; Y10S 977/774; Y10S 977/948; B82Y 30/00
USPC 136/255; 977/774; 977/948

(57) ABSTRACT

An solar cell of the present invention includes a p-type semiconductor layer, an n-type semiconductor layer, and a superlattice semiconductor layer interposed between the p-type semiconductor layer and the n-type semiconductor layer, in which the superlattice semiconductor layer has a superlattice structure in which barrier layers and quantum dot layers each including a plurality of quantum dots are stacked alternately and repeatedly, the superlattice semiconductor layer contains an n-type dopant and has at least two intermediate energy levels at which electrons photoexcited from the valence band of the quantum dots or the barrier layers can be present for a certain period of time, each of the intermediate energy levels is located between the top of the valence band of the barrier layers and the bottom of the conduction band of the barrier layers, each of the intermediate energy levels is formed from one or a plurality of quantum levels of the quantum dots, and the superlattice semiconductor layer contains an activated n-type dopant.

### TECHNICAL FIELD

The present invention relates to a solar cell having a superlattice structure.

### BACKGROUND ART

In recent years, photovoltaic devices have been receiving attention as a clean energy source that does not emit CO₂ and are becoming increasingly popular. Currently, the most popular photovoltaic devices are single-junction solar cells with silicon. However, energy conversation efficiency is approaching the Shockley-Queisser theoretical limit (hereinafter, referred to as the “SQ theoretical limit”). For this reason, there have been advances in the development of third-generation solar cells exceeding the SQ theoretical limit.

Intermediate-band solar cells with intermediate bands (also referred to as “minibands” when quantum structures are used) or localized levels (also referred to as “quantum levels” when quantum structures are used) in forbidden bands have been reported as third-generation solar cells. For intermediate-band solar cells, the formation of intermediate bands in forbidden bands of matrix semiconductors enables electronic excitation from valence bands to intermediate bands and electronic excitation from intermediate bands to conduction bands, thus absorbing light having lower energy than band gaps of matrix semiconductors. For this reason, intermediate-band solar cells promise to provide high energy conversion efficiency.

Examples of a method for forming a layer capable of absorbing lower energy than the band gap of a matrix semiconductor (hereinafter, referred to as an “active layer region”) in an intermediate-band solar cell include a method in which quantum dots are used, a method in which a quantum well is used, a method in which a highly mismatched material is used, and a method in which an impurity is injected in high concentration. Among these, for example, it is known that an active layer region where an intermediate band is formed with quantum dots is preferably doped in a concentration of half the density of states of the intermediate band (for example, NPLs 1 and 2). NPL 3 reports a case in which a quantum dot region is doped with up to six electrons per quantum dot to produce a quantum dot solar cell.

### CITATION LIST

### Non Patent Literature

NPL 1: A. Luque, et. al., Journal of Applied Physics 99, 094503 (2006)
NPL 2: K. Yoshida, et. al., Applied Physics Letters 97, 133503 (2010)
NPL 3: K. A. Sablon et. al., Nano Letters 11, 2311 (2011)

### SUMMARY OF INVENTION

### Technical Problem

However, in conventional intermediate-band solar cells, detailed studies are not conducted on a doping concentration in an active layer region of an intermediate-band solar cell with two or more intermediate bands or localized levels.

The present invention has been accomplished in light of the foregoing circumstances and provides a solar cell with high energy conversion efficiency.

### Solution to Problem

The present invention provides a solar cell including a p-type semiconductor layer, an n-type semiconductor layer, and a superlattice semiconductor layer interposed between the p-type semiconductor layer and the n-type semiconductor layer, in which the superlattice semiconductor layer has a superlattice structure in which barrier layers and quantum dot layers each including a plurality of quantum dots are stacked alternately and repeatedly, the superlattice semiconductor layer contains an n-type dopant and has at least two intermediate energy levels at which electrons photoexcited from the valence band of the quantum dots or the barrier layers can be present for a certain period of time, each of the intermediate energy levels is located between the top of the valence band of the barrier layers and the bottom of the conduction band of the barrier layers, each of the intermediate energy levels is formed from one or a plurality of quantum levels of the quantum dots, and the superlattice semiconductor layer contains an activated n-type dopant.

### Advantageous Effects of Invention

According to the present invention, the p-type semiconductor layer, the n-type semiconductor layer, and the superlattice semiconductor layer interposed between the p-type semiconductor layer and the n-type semiconductor layer are provided, thereby generating photovoltaic power.

According to the present invention, the superlattice semiconductor layer has a superlattice structure in which barrier layers and quantum dot layers each including a plurality of quantum dots are stacked alternately and repeatedly. Thus, the superlattice semiconductor layer has intermediate energy levels in the band gap of the barrier layers. The superlattice semiconductor layer has at least two intermediate energy levels. Thus, the superlattice semiconductor layer enables electrons in the valence band of the barrier layers to be excited to the conduction band of the barrier layers via the intermediate energy levels using light having a longer wavelength than light absorbed by the forbidden band of the barrier layers, thereby improving the photoelectric conversion efficiency.

### BRIEF DESCRIPTION OF DRAWINGS

FIG. 1 is a schematic cross-sectional view of a configuration of a solar cell according to an embodiment of the present invention.

FIG. 2 is a schematic band diagram of a superlattice semiconductor layer in a solar cell according to an embodiment of the present invention.

FIG. 3 is a schematic band diagram of a superlattice semiconductor layer in a solar cell according to an embodiment of the present invention.

FIG. 4 is a schematic cross-sectional view of a configuration of a solar cell according to an embodiment of the present invention.

FIG. 5 is a schematic band diagram of a superlattice semiconductor layer in a solar cell according to an embodiment of the present invention.

FIG. 6 is a schematic band diagram of a superlattice semiconductor layer in a solar cell according to an embodiment of the present invention.

FIG. 7 is a schematic cross-sectional view of a configuration of a solar cell according to an embodiment of the present invention.

FIG. 8 is a schematic band diagram of a superlattice semiconductor layer in a solar cell according to an embodiment of the present invention.

FIG. 9 is a schematic band diagram of a superlattice semiconductor layer in a solar cell according to an embodiment of the present invention.

FIG. 10 is a schematic cross-sectional view of a configuration of a solar cell according to an embodiment of the present invention.

FIG. 11 is a schematic cross-sectional view of a configuration of a solar cell according to an embodiment of the present invention.

FIG. 12 is a schematic band diagram of a superlattice semiconductor layer in a solar cell according to an embodiment of the present invention.

FIG. 13 is a schematic band diagram of a superlattice semiconductor layer in a solar cell according to an embodiment of the present invention.

FIG. 14 is a schematic band diagram of a superlattice semiconductor layer in a solar cell according to an embodiment of the present invention.

FIG. 15 is a schematic band diagram of a superlattice semiconductor layer in a solar cell according to an embodiment of the present invention.

FIG. 16 is a schematic band diagram of a superlattice semiconductor layer in a solar cell according to an embodiment of the present invention.

FIG. 17 is a schematic band diagram of a superlattice semiconductor layer in a solar cell according to an embodiment of the present invention.

FIG. 18 is a schematic band diagram of a superlattice semiconductor layer in a solar cell according to an embodiment of the present invention.

FIG. 19 is a graph illustrating the results of a simulation experiment.

FIG. 20 is a graph illustrating the results of a simulation experiment.

FIG. 21 is a graph illustrating the results of a simulation experiment.

FIG. 22 is a graph illustrating the results of a simulation experiment.

FIG. 23 is a graph illustrating the results of a simulation experiment.

FIG. 24 is a graph illustrating the results of a simulation experiment.

FIG. 25 is a graph illustrating the results of a simulation experiment.

FIG. 26 is a graph illustrating the results of a simulation experiment.

FIG. 27 is a graph illustrating the results of a simulation experiment.

FIG. 28 is a graph illustrating the results of a simulation experiment.

FIG. 29 is a graph illustrating the results of a simulation experiment.

FIG. 30 is a graph illustrating the results of a simulation experiment.

FIG. 31 is a graph illustrating the results of a simulation experiment.

FIG. 32 is a graph illustrating the results of a simulation experiment.

FIG. 33 is a graph illustrating the results of a simulation experiment.

FIG. 34 is a graph illustrating the results of a simulation experiment.

FIG. 35 is a graph illustrating the results of a simulation experiment.

FIG. 36 is a graph illustrating the results of a simulation experiment.

FIG. 37 is a graph illustrating the results of a simulation experiment.

FIG. 38 is a graph illustrating the results of a simulation experiment.

FIG. 39 is a graph illustrating the results of a simulation experiment.

FIG. 40 is a graph illustrating the results of a simulation experiment.

FIG. 41 is a graph illustrating the results of a simulation experiment.

FIG. 42 is a graph illustrating the results of a simulation experiment.

FIG. 43 is a graph illustrating the results of a simulation experiment.

FIG. 44 is a graph illustrating the results of a simulation experiment.

FIG. 45 is a graph illustrating the results of a simulation experiment.

FIG. 46 is a graph illustrating the results of a simulation experiment.

FIG. 47 is a graph illustrating the results of a simulation experiment.

FIG. 48 is a graph illustrating the results of a simulation experiment.

FIG. 49 is a graph illustrating the results of a simulation experiment.

FIG. 50 is a graph illustrating the results of a simulation experiment.

### DESCRIPTION OF EMBODIMENTS

A solar cell of the present invention includes a p-type semiconductor layer, an n-type semiconductor layer, and a superlattice semiconductor layer interposed between the p-type semiconductor layer and the n-type semiconductor layer, in which the superlattice semiconductor layer has a superlattice structure in which barrier layers and quantum dot layers each including a plurality of quantum dots are stacked alternately and repeatedly, the superlattice semiconductor layer contains an n-type dopant and has at least two intermediate energy levels at which electrons photoexcited from the valence band of the quantum dots or the barrier layers can be present for a certain period of time, each of the intermediate energy levels is located between the top of the valence band of the barrier layers and the bottom of the conduction band of the barrier layers, each of the intermediate energy levels is formed from one or a plurality of quantum levels of the quantum dots, and the superlattice semiconductor layer contains an activated n-type dopant in an atomic concentration of 0.1 or more times and 1.5 or less times as large as the sum total of the densities of states of the intermediate energy levels.

In the present invention, the p-type semiconductor layer, the n-type semiconductor layer, and the superlattice semiconductor layer constitute a photoelectric conversion layer.

In the present invention, the superlattice structure refers to a structure in which the barrier layers and the quantum dot layers, which are composed of semiconductor materials and have different band gaps, are stacked alternately and repeatedly. The wave function of an electron in a quantum dot layer may interact significantly with the wave function of an electron in adjacent quantum dot layer.

In the present invention, the quantum dots refer to semiconductor fine particles each having a particle size of 100 nm or less, each of the fine particles being surrounded by a semiconductor having a larger band gap than the semiconductor constituting the quantum dots.

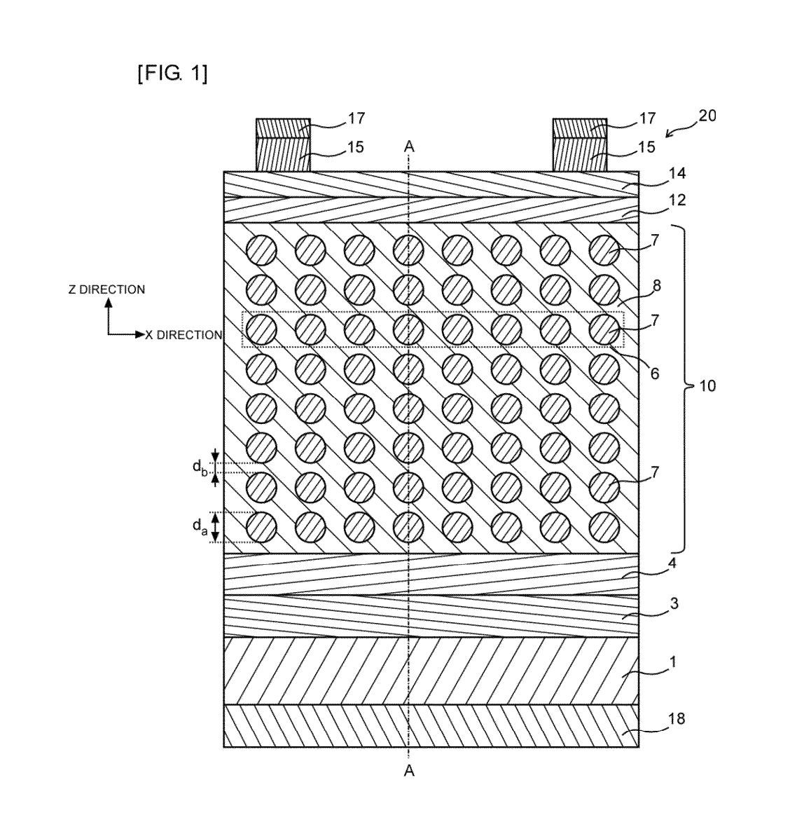

In the present invention, each of the quantum dot layers refers to a layer including a plurality of quantum dots and serves as a well layer. In the present invention, the size of the quantum dot layer refers to the size of the quantum dots in the quantum dot layer in a direction (the z-direction in FIG. 1) in which the barrier layers and the quantum dot layers are stacked alternately and repeatedly as long as there is no discrepancy.

In the present invention, each of the barrier layers is composed of a semiconductor material having a wider band gap than the semiconductor material constituting the quantum dots and forms a potential barrier around the quantum dots.

In the present invention, each of the intermediate energy levels refers to an energy level at which an electron photoexcited from the valence band of the quantum dots or the barrier layers can be present for a certain period of time, the energy level being located between the top of the valence band of the barrier layers and the bottom of the conduction band of the barrier layers and being formed from one or a plurality of quantum levels of the quantum dots. Each of the intermediate energy levels indicates, for example, an intermediate band or a localized level. All the intermediate energy levels of the superlattice semiconductor layer may be formed from one or a plurality of quantum levels on the conduction-band side of the quantum dots. Alternatively, among the intermediate energy levels of the superlattice semiconductor layer, one of the intermediate energy levels may be formed from one or a plurality of quantum levels on the valence-band side of the quantum dots, and the other intermediate energy levels may be formed from one or a plurality of quantum levels on the conduction-band side of the quantum dots.

In the present invention, the intermediate band refers to a continuous band in the forbidden band of the semiconductor constituting the barrier layers. The electron wave function of the quantum dot layer in the superlattice structure interacts with electron wave functions of adjacent quantum dot layers to provide a resonant tunneling effect between the quantum levels of the quantum dots, so that the quantum levels are coupled to one another to form an intermediate band, which is also referred to as a “miniband”.

In the present invention, the localized levels refer to energy levels formed in the forbidden band of the semiconductor constituting the barrier layers, the energy levels being discontinuous energy levels. Discrete electron energy levels formed in the quantum dots surrounded by the potential barrier are also referred to as “quantum levels”. The quantum levels are also referred to as “quantum energy levels”.

In the present invention, the density of states of the intermediate energy level refers to a value twice as large as the number of energy states that can be taken by the intermediate energy level (the intermediate band or localized level) per unit volume. Specifically, the value is obtained by multiplying the number of quantum levels originating from one quantum dot by the density of the quantum dots and multiplying the product by two.

In the present invention, the activated n-type dopant refers to a dopant atom that is formed into a monovalent cation by ejecting an electron from the dopant atom. In the superlattice semiconductor layer, the electron ejected from the dopant atom is preferably present at the intermediate energy level. The rate of the dopant atom that is formed into the monovalent cation to the dopant atom that is not formed into a cation is referred to as an “activation rate”.

In the solar cell of the present invention, the superlattice semiconductor layer preferably contains the activated n-type dopant in an atomic concentration of 0.1 or more times and 1.5 or less times as large as the sum total of the densities of states of the intermediate energy levels.

In this configuration, as is apparent from experiments conducted by the inventors, an appropriate number of electrons can be present, and electrons in the valence band of the barrier layers or the quantum dots can be efficiently photoexcited to the conduction band of the barrier layers via the intermediate energy levels, thereby improving the photoelectric conversion efficiency of the solar cell.

In the solar cell of the present invention, preferably, the number of the intermediate energy levels in the superlattice semiconductor layer is two, and the superlattice semiconductor layer contains the activated n-type dopant in an atomic concentration of 0.1 or more times and 1.5 or less times as large as the sum total of the densities of states of the intermediate energy levels.

In this configuration, an appropriate number of electrons can be present in each quantum dot, and electrons in the valence band of the barrier layers or the quantum dots can be efficiently photoexcited to the conduction band of the barrier layers via the intermediate energy levels, thereby improving the photoelectric conversion efficiency of the solar cell.

In the solar cell of the present invention, preferably, the number of the intermediate energy levels in the superlattice semiconductor layer is three, and the superlattice semiconductor layer contains the activated n-type dopant in an atomic concentration of 0.13 or more times and 1.20 or less times as large as the sum total of the densities of states of the intermediate energy levels.

In this configuration, an appropriate number of electrons can be present in each quantum dot, and electrons in the valence band of the barrier layers or the quantum dots can be efficiently photoexcited to the conduction band of the barrier layers via the intermediate energy levels, thereby improving the photoelectric conversion efficiency of the solar cell.

In the solar cell of the present invention, preferably, the number of the intermediate energy levels in the superlattice semiconductor layer is four, and the superlattice semiconductor layer contains the activated n-type dopant in an atomic concentration of 0.18 or more times and 1 or less times as large as the sum total of the densities of states of the intermediate energy levels.

In this configuration, an appropriate number of electrons can be present in each quantum dot, and electrons in the valence band of the barrier layers or the quantum dots can be efficiently photoexcited to the conduction band of the barrier layers via the intermediate energy levels, thereby improving the photoelectric conversion efficiency of the solar cell.

In the solar cell of the present invention, preferably, the quantum dots contained in one quantum dot layer have substantially the same size in a direction in which the barrier layers and the quantum dot layers are repeatedly stacked, and the quantum dots contained in the quantum dot layers that are contained in the superlattice semiconductor layer have substantially the same size in the direction in which the barrier layers and the quantum dot layers are repeatedly stacked.

In this configuration, the quantum dot layers in the superlattice semiconductor layer can be formed in the same method, thereby reducing the production cost.

In the solar cell of the present invention, preferably, the quantum dots contained in one quantum dot layer have substantially the same size in a direction in which the barrier layers and the quantum dot layers are repeatedly stacked, the superlattice semiconductor layer has a structure in which a plurality of types of the quantum dot layers are periodically stacked, and the quantum dots contained in the plurality of types of the quantum dot layers have different sizes in the direction in which the barrier layers and the quantum dot layers are repeatedly stacked.

In this configuration, the different types of the quantum dot layers can have different intermediate energy levels, so that the superlattice semiconductor layer can have a plurality of the intermediate energy levels.

In the solar cell of the present invention, preferably, the quantum dots contained in one quantum dot layer are composed of the same material, the superlattice semiconductor layer has a structure in which a plurality of types of the quantum dot layers are periodically stacked, and the quantum dots contained in the plurality of types of the quantum dot layers are composed of different materials.

In this configuration, the different types of the quantum dot layers can have different intermediate energy levels, so that the superlattice semiconductor layer can have a plurality of the intermediate energy levels.

In the solar cell of the present invention, preferably, the quantum dots contained in one quantum dot layer contain the same type of the n-type dopant, the superlattice semiconductor layer has a structure in which a plurality of types of the quantum dot layers are periodically stacked, and the quantum dots contained in the plurality of types of the quantum dot layers contain different types of the n-type dopants.

In this configuration, electrons are allowed to be easily present at the intermediate energy levels, thereby increasing optical transitions via the intermediate energy levels.

In the solar cell of the present invention, upon letting the number of the intermediate energy levels in the superlattice semiconductor layer be x, the superlattice semiconductor layer preferably has x types of the quantum dot layers.

In this configuration, when each of the different types of the quantum dot layers has one intermediate energy level, it is possible to control the number of the intermediate energy levels in response to the number of the types of the quantum dot layers.

In the solar cell of the present invention, preferably, the number of the intermediate energy levels in the superlattice semiconductor layer is two, three, or four.

In this configuration, electrons in the valence band can be photoexcited to the conduction band via the intermediate energy levels, thereby improving the photoelectric conversion efficiency.

In the solar cell of the present invention, preferably, the intermediate energy levels are intermediate bands or localized levels.

In this configuration, electrons in the valence band can be photoexcited to the conduction band via the intermediate bands or the localized levels, thereby improving the photoelectric conversion efficiency.

In the solar cell of the present invention, preferably, the intermediate energy levels are formed from one or a plurality of quantum levels on the conduction-band side of the quantum dots.

In this configuration, the intermediate energy levels can be formed by the quantum levels on the conduction-band side of the quantum dots.

In the solar cell of the present invention, preferably, the barrier layers contains n-type dopants, the superlattice semiconductor layer has a structure in which a plurality of types of the barrier layers are periodically stacked, and the plurality of types of the barrier layers contain different types of the n-type dopants.

In this configuration, electrons are allowed to be easily present at the intermediate energy levels, thereby increasing optical transitions via the intermediate energy levels.

In the solar cell of the present invention, the intermediate energy levels are preferably formed on the conduction-band side of the quantum dots contained in the superlattice semiconductor layer. In this case, the probability of photoexcitation via the intermediate energy levels is increased, thereby improving the photoelectric conversion efficiency.

In the solar cell of the present invention, a band offset on the valence-band side is preferably close to zero. The reason for this is that heavy holes are present in the valence band, the quantum energy levels on the valence-band side and the valence band of the barrier layers are often regarded as a substantially single valence band, and the degree of electronic coupling of wave functions is greater as the band offset on the valence-band side is closer to zero.

An embodiment of the present invention will be described below with reference to the drawings. Configurations illustrated in the drawings and the following description are illustrative, and the scope of the present invention is not limited to the drawings and the following description.

### Structure of Solar Cell

FIG. 1 is a schematic cross-sectional view illustrating a configuration of a solar cell according to an embodiment of the present invention. FIG. 1 illustrates a solar cell in which quantum dots 7 in quantum dot layers 6 have a constant size dₐ in the z direction and a barrier layer between two adjacent quantum dot layers has a constant thickness d_{b}.

A solar cell 20 according to this embodiment includes a p-type semiconductor layer 4, an n-type semiconductor layer 12, and a superlattice semiconductor layer 10 interposed between the p-type semiconductor layer 4 and the n-type semiconductor layer 12, in which the superlattice semiconductor layer 10 has a superlattice structure in which barrier layers 8 and the quantum dot layers 6 are stacked alternately and repeatedly, the superlattice semiconductor layer 10 contains an n-type dopant and has at least two intermediate energy levels at which electrons photoexcited from the valence band of the quantum dots 7 or the barrier layers 8 can be present for a certain period of time, each of the intermediate energy levels is located between the top of the valence band of the barrier layers 8 and the bottom of the conduction band of the barrier layers 8 and is formed from one or a plurality of quantum levels of the quantum dots 7, and the superlattice semiconductor layer 10 contains an activated n-type dopant.

The solar cell 20 according to this embodiment will be described below.

1. P-Type Semiconductor Layer (Base Layer) and n-Type Semiconductor Layer (Emitter Layer)

The p-type semiconductor layer (base layer) 4 is composed of a semiconductor containing a p-type impurity. The n-type semiconductor layer (emitter layer) 12 is composed of a semiconductor containing an n-type impurity.

The p-type semiconductor layer 4 and the n-type semiconductor layer 12 sandwich the superlattice semiconductor layer 10 to form the solar cell 20. The entrance of light to these layers generates photovoltaic power.

The p-type semiconductor layer 4 and the n-type semiconductor layer 12 may be formed by, for example, an MOCVD method.

The p-type semiconductor layer 4 may be electrically connected to a p-type electrode 18. The n-type semiconductor layer 12 may be electrically connected to an n-type electrode 17. Thereby, photovoltaic power generated between the p-type semiconductor layer 4 and the n-type semiconductor layer 12 can be output to an external circuit through the p-type electrode 18 and the n-type electrode 17. Furthermore, a contact layer 15 may be provided between the p-type semiconductor layer 4 and the p-type electrode 18 or between the n-type semiconductor layer 17 and the n-type electrode 17.

### 2. Superlattice Semiconductor Layer

The superlattice semiconductor layer 10 is sandwiched between the p-type semiconductor layer (base layer) 4 and the n-type semiconductor layer (emitter layer) 12. The superlattice semiconductor layer 10 has a superlattice structure in which the quantum dot layers 6 and the barrier layers 8 are stacked alternately and repeatedly.

Each of the quantum dot layers 6 is a layer containing a plurality of quantum dots 7. The quantum dots 7 are composed of a semiconductor material having a narrower band gap than a semiconductor material constituting the barrier layers 8 and have a quantum level on the conduction-band side by virtue of a quantum effect. Each of the quantum dots 7 in the quantum dot layers 6 has a quantum level on the conduction-band side.

The plural quantum dot layers 6 in the superlattice semiconductor layer 10 may be composed of all the same material or may include the quantum dot layer 6 composed of a different material. In the case where the plural quantum dot layers 6 in the superlattice semiconductor layer 10 are composed of a mixed crystal, the plural quantum dot layers 6 may contain the quantum dot layer 6 composed of a mixed crystal having a different mixed crystal ratio.

The plural quantum dots 7 in one quantum dot layer 6 may have substantially the same size in a direction in which the barrier layers 8 and the quantum dot layers 6 are repeatedly stacked (in the z direction in FIG. 1). In the case where the superlattice semiconductor layer 10 includes the plural quantum dot layers 6, the quantum dots 7 in the quantum dot layers 6 may have the same size in the direction in which the barrier layers 8 and the quantum dot layers 6 are repeatedly stacked (in the z direction in FIG. 1) for all quantum dot layers 6 or may have different sizes for each quantum dot layer 6.

The plural quantum dots 7 in one quantum dot layer 6 may have substantially the same size in a direction parallel to the quantum dot layers 6 (in the x direction in FIG. 1) (y direction). In the case where the superlattice semiconductor layer 10 includes the plural quantum dot layers 6, the quantum dots 7 in the quantum dot layers 6 may have the same size in the x direction (y direction) for all quantum dot layers 6 or may have different sizes for each quantum dot layer 6.

Each of the quantum dots 7 in the quantum dot layers 6 may have substantially the same size in the x direction, the y direction, and the z direction.

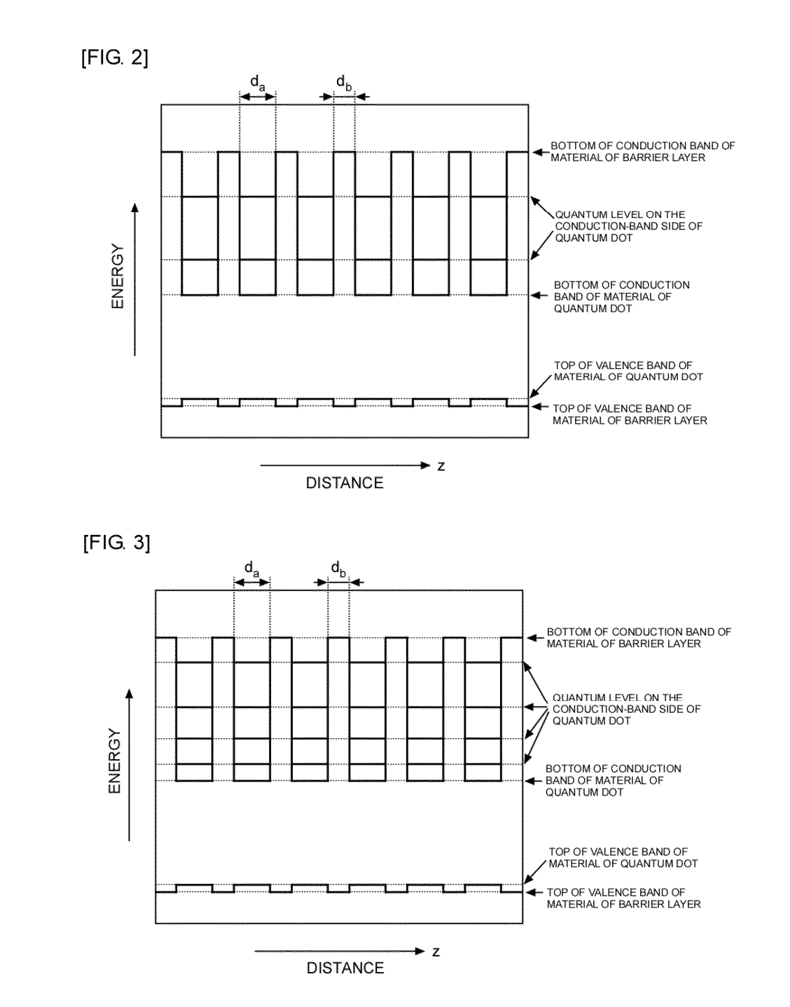

The sizes of the quantum dots in the x direction, the y direction, and the z direction may be appropriately changed, depending on the desired number of energy levels. In the case where the same number of the intermediate energy levels having the same energy value is formed, the quantum dots may be made uniform in size in all of the x direction, the y direction, and the z direction. For example, FIGS. 2 and 3 illustrate this case.

The barrier layers 8 are composed of a semiconductor material having a wider band gap than a semiconductor material constituting the quantum dots 7 and form potential barriers around the quantum dots 7.

In this embodiment, the solar cell 20 may include, for example, the quantum dot layers 6 composed of InGaAs and the barrier layers 8 composed of AlGaAs in the superlattice semiconductor layer 10. Alternatively, the quantum dot layers 6 composed of InAsSb and the barrier layers 8 composed of AlAsSb may be used. In addition, materials of InAs, GaAs, AlAs, InSb, GaSb, AlSb, InP, GaP, and AlP, and mixed crystal materials thereof may be used for the superlattice semiconductor layer 10. Furthermore, AlₓGa_{y}In_{1-x-y}As, AlₓGa_{y}In_{1-x-y}Sb_{z}As_{1-z}, AlₓGa_{y}In_{1-x-y}P, AlₓGa_{y}In_{1-x-y}N, and so forth may be used as materials constituting the barrier layers 8 and the quantum dot layers 6 included in the superlattice semiconductor layer 10. Group III-V compound semiconductors, chalcopyrite-based materials, group II-VI compound semiconductors, group IV semiconductors, and mixed crystal materials thereof may be used other than listed above.

In the case of the quantum dot layers 6 and the barrier layers 8 composed of mixed crystals, an appropriate change in the proportions of elements enables lattice constants to be set to desired values or to be changed to values in response to a substrate and enables the valence band energy offset (difference in valence band energy between the quantum dot layers and the barrier layers) to be set to zero.

Heavy holes are present in the valence band, so the quantum energy levels on the valence-band side are densely formed. Thus, the quantum energy levels on the valence-band side and the valence band of the barrier layers are often regarded as a substantially single valence band. In this case, the localized levels and the intermediate bands on the valence-band side are not included in the number of the intermediate energy levels. The sentence “the quantum energy levels on the valence-band side are densely formed” indicates that, for example, the difference in energy between adjacent quantum energy levels is lower than a value about twice the room-temperature energy (about 25 meV).

The superlattice semiconductor layer 10 has at least two intermediate energy levels at which electrons photoexcited from the valence band of the quantum dots 7 or the barrier layers 8 can be present for a certain period of time, each of the intermediate energy levels is located between the top of the valence band of the barrier layers 8 and the bottom of the conduction band of the barrier layers 8. Whether the intermediate energy levels, at which electrons photoexcited from the valence band of the quantum dots 7 or the valence band of the barrier layers 8 can be present for a certain period of time, are present may be determined by measuring an emission spectrum using, for example, photoluminescence (PL) measurement.

Two of more intermediate energy levels are formed in the superlattice semiconductor layer 10. The number of the intermediate energy levels may be determined by the foregoing PL measurement or an optical absorption spectrum.

The intermediate energy levels may be intermediate bands or localized levels.

In the case where the intermediate energy levels are the intermediate bands, when the wave functions of the quantum levels of the quantum dots 7 are electronically coupled to form a band, the number of the intermediate energy levels is defined as 1.

In the case where the intermediate energy levels are localized levels, when the localized levels have substantially the same energy value, the number of the intermediate energy levels is defined as 1. The phrase “substantially the same energy value” indicates that, for example, the difference in energy value between the localized levels is lower than a value about twice the room-temperature energy (about 25 meV).

In this embodiment, hereinafter, the solar cell including the superlattice semiconductor layer 10 that has an energy level constituting the bottom of the conduction band of the barrier layers 8, an energy level constituting the top of the valence band of the barrier layers 8, and two intermediate energy levels between these levels is referred to as a “4-level intermediate-band solar cell” in this specification. The intermediate energy levels may be intermediate bands.

In an embodiment, a solar cell including the superlattice semiconductor layer 10 that has an energy level constituting the bottom of the conduction band of the barrier layers 8, an energy level constituting the top of the valence band of the barrier layers 8, and three intermediate energy levels between these levels is referred to as a “5-level intermediate-band solar cell” in this specification. The intermediate energy levels may be intermediate bands.

In an embodiment, a solar cell including the superlattice semiconductor layer 10 that has an energy level constituting the bottom of the conduction band of the barrier layers 8, an energy level constituting the top of the valence band of the barrier layers 8, and four intermediate energy levels between these levels is referred to as a “6-level intermediate-band solar cell” in this specification. The intermediate energy levels may be intermediate bands.

Each of the plural intermediate energy levels of the superlattice semiconductor layer 10 has the density of states.

The density of states of each intermediate energy level refers to a value twice as large as the number of energy states that can be taken by the intermediate energy level (the intermediate band or localized level) per unit volume. Specifically, the value is obtained by multiplying the number of quantum levels originating from one quantum dot by the density of the quantum dots and multiplying the product by two.

The density of states of the intermediate energy level may be determined by, for example, photoelectron spectroscopy (PES), ultraviolet photoelectron spectroscopy (UPS), or X-ray photoelectron spectroscopy (XPS). In the case of a superlattice structure including quantum dots, the density of the quantum dots may be determined by transmission electron microscopy (TEM) observation, the number of energy levels may be determined by photoluminescence (PL) measurement, and then the density of states may be calculated.

The superlattice semiconductor layer 10 contains an n-type dopant (n-type impurity). This enables electrons to be present in the intermediate energy levels. The n-type dopant may be present in the quantum dots 7 and may be present in the barrier layers 8. The presence of electrons in the intermediate energy levels may result in the increase of optical transitions via the intermediate energy levels.

The superlattice semiconductor layer 10 contains the activated n-type dopant in an atomic concentration of 0.1 or more times and 1.5 or less times as large as the sum total of the densities of states of the intermediate energy levels. In other words, upon letting the number of the intermediate energy levels of the superlattice semiconductor layer 10 be x (x≧2), letting the densities of states of the intermediate energy levels be Y₁, Y₂, . . . , and Yₓ, letting Yₜₒₜₐₗ=Y₁+Y₂+ . . . +Yₓ, and letting the concentration of the activated n-type doping in the superlattice structure be N_{d}, the expression 0.1≦N_{d}/Yₜₒₜₐₗ≦1.5 is satisfied.

This enables an appropriate number of electrons to be present at the intermediate energy levels and enables electrons in the valence band of the barrier layers 8 or the quantum dots 7 to be efficiently photoexcited to the conduction band of the barrier layers 8 via the intermediate energy levels, thereby improving the photoelectric conversion efficiency of the solar cell 20.

Here, a 4-level intermediate-band solar cell which exhibits a schematic band diagram illustrated in FIG. 2 will be described, the solar cell including two intermediate energy levels between the valence band of the barrier layers 8 and the conduction band of the barrier layers 8.

FIG. 2 is a schematic band diagram of the superlattice semiconductor layer 10 taken along alternate long and short dashed line A-A in FIG. 1. Each of the quantum dots 7 has two quantum levels.

In the 4-level intermediate-band solar cell, upon letting the densities of states of the intermediate energy levels be Y₁ and Y₂, letting Yₜₒₜₐₗ=(Y₁+Y₂) and letting the concentration of the activated n-type dopant in the superlattice semiconductor layer 10 be N_{d}, the superlattice semiconductor layer 10 preferably contains the n-type dopant in such a manner that 0.1≦N_{d}/Yₜₒₜₐₗ≦1.5 is satisfied. In other words, the superlattice semiconductor layer 10 preferably has two intermediate energy levels, and the superlattice semiconductor layer 10 preferably contains the activated n-type dopant in an atomic concentration of 0.1 or more times and 1.5 or less times as large as the sum total of the densities of states of the intermediate energy levels. Furthermore, the superlattice semiconductor layer 10 preferably contains the activated n-type dopant in an atomic concentration of 0.5 times as large as the sum total of the densities of states of the intermediate energy levels. Such a configuration enables an appropriate number of electrons to be present in the quantum dots 7 and enables electrons in the valence band of the barrier layers 8 or the quantum dots 7 to be efficiently photoexcited to the conduction band of the barrier layers 8 via the intermediate energy levels, thereby improving the photoelectric conversion efficiency of the solar cell.

The superlattice semiconductor layer 10 having the two intermediate bands may be formed by adjusting, for example, the size of the quantum dot layers 6. For example, the formation of quantum dot layers composed of InGaAs on barrier layers composed of AlGaInAs, quantum dot layers composed of InGaN on barrier layers composed of AlGaN, or quantum dot layers composed of InAsSb on barrier layers composed of AlSbAs enables two intermediate bands to be formed in the superlattice semiconductor layer 10. Thus, as illustrated in the schematic cross-sectional view of FIG. 1, the 4-level intermediate-band solar cell may be produced by repeatedly stacking the quantum dot layers 6 having the same size.

As described above, the selection of the semiconductor materials having appropriate physical properties and the adjustment of the mixed crystal ratio of the semiconductor materials constituting the superlattice semiconductor layer 10 enables the formation of the superlattice semiconductor layer 10 having desired intermediate bands and localized energy levels. Furthermore, the adjustment of the size of the quantum dots 7 and the thickness of the barrier layers 8 constituting the superlattice semiconductor layer 10 also enables the formation of the superlattice semiconductor layer 10 having desired intermediate bands and localized energy levels. The same is true for, for example, a 5-level intermediate-band solar cell and a 6-level intermediate-band solar cell described below.

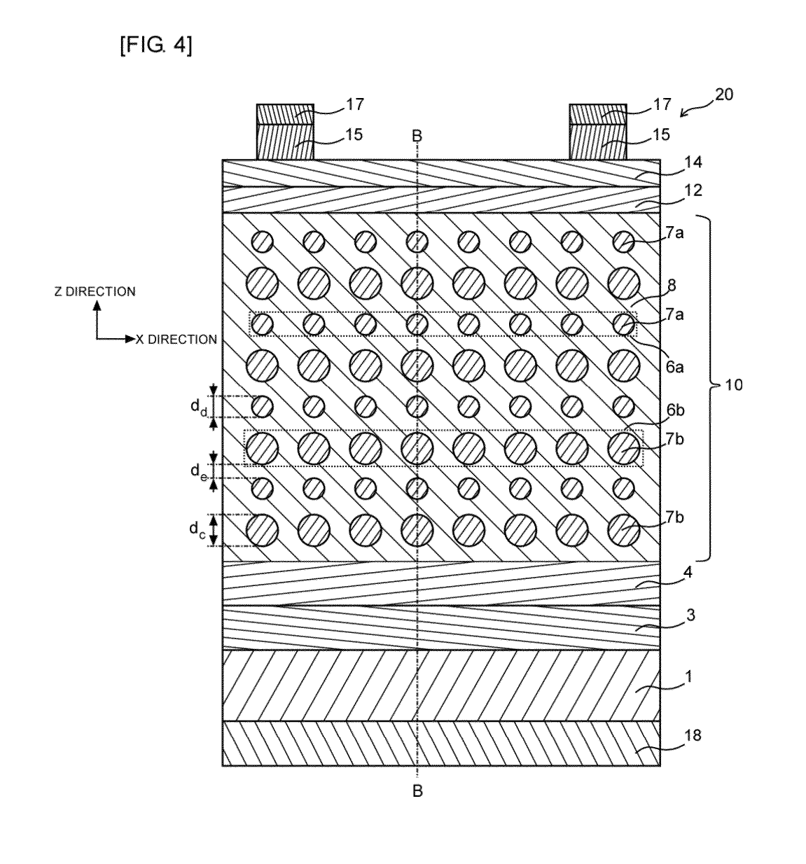

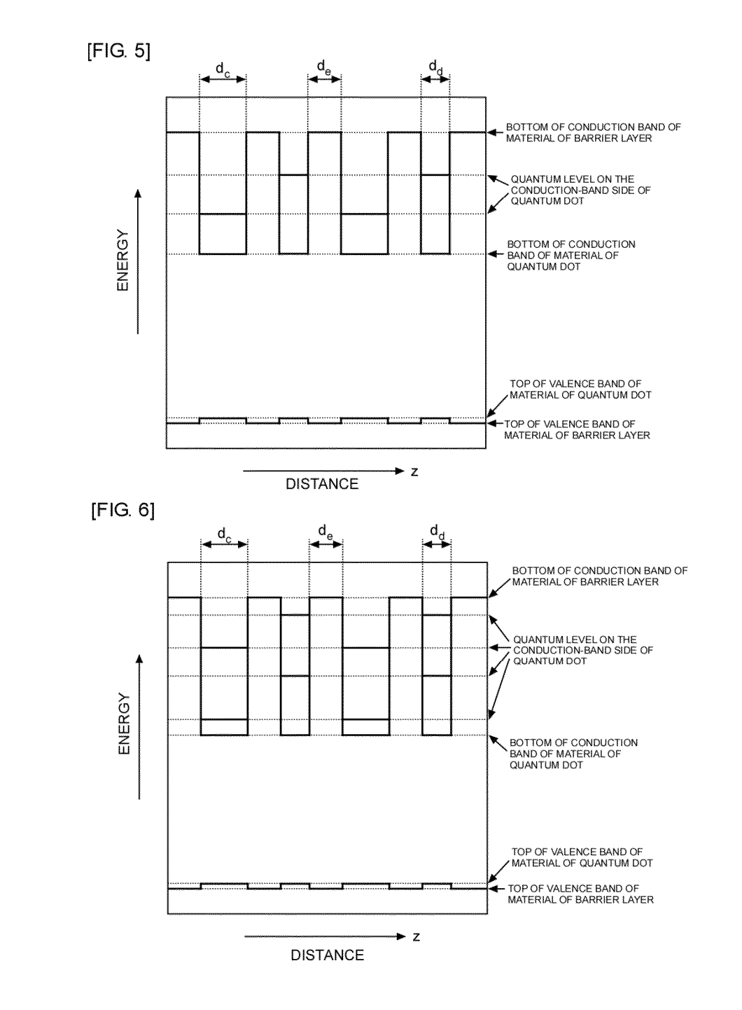

A 4-level intermediate-band solar cell may also be produced by alternately and repeatedly stacking quantum dot layers 6a and 6b having two different sizes in the z direction as illustrated in the schematic cross-sectional view of FIG. 4. FIG. 5 is a schematic diagram of a band structure of the superlattice semiconductor layer 10 taken along alternate long and short dashed line B-B in FIG. 4. Quantum dots 7a and 7b each have one intermediate energy level. The small-sized quantum dots 7a have a size of d_{d} in the z direction and quantum levels with higher energy on the conduction-band side in FIG. 5. The large-sized quantum dots 7b have a size of d_{c} in the z direction and quantum levels with lower energy on the conduction-band side in FIG. 5.

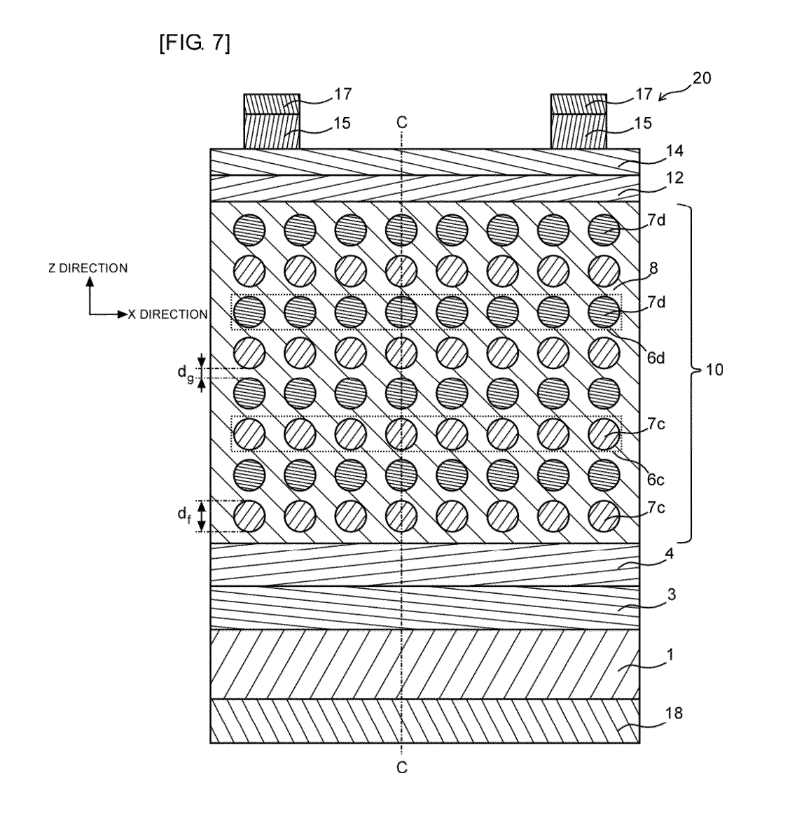

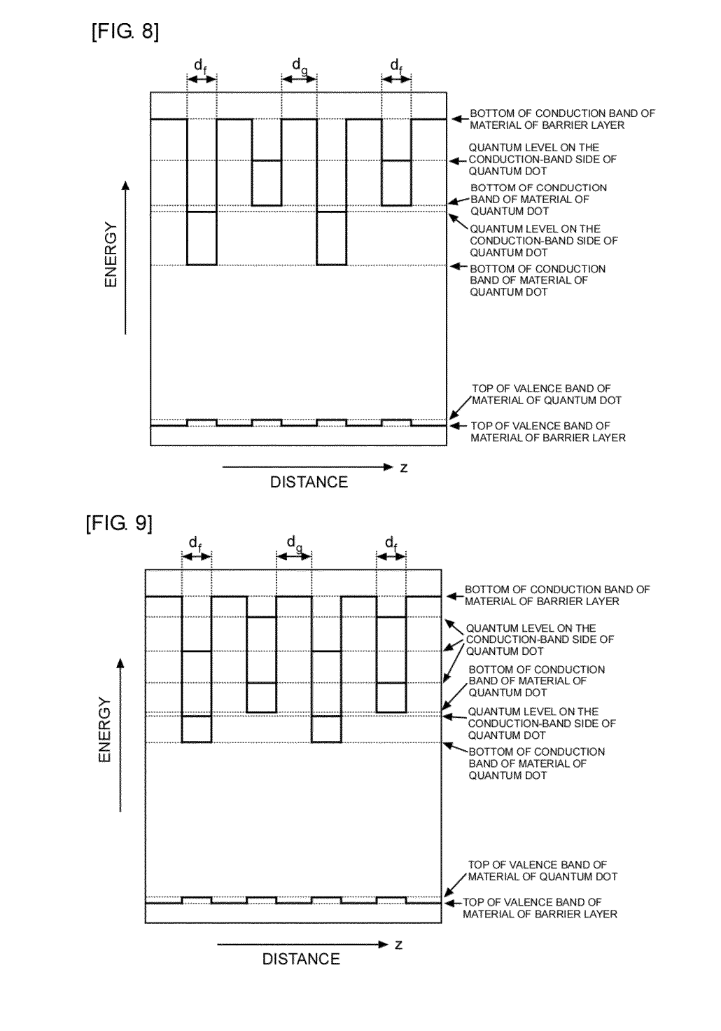

Furthermore, a 4-level intermediate-band solar cell may be produced by alternately and repeatedly stacking quantum dot layers 6c and 6d composed of two different materials (including the case of different mixed crystal ratios) as illustrated in the schematic cross-sectional view of FIG. 7. In FIG. 7, the quantum dots have the same size in the z direction. FIG. 8 is a schematic band diagram of the superlattice semiconductor layer 10 taken along alternate long and short dashed line C-C in FIG. 7. Quantum dots 7c and 7d each have one intermediate energy level. In this case, the total number of the intermediate energy levels is two, thus resulting in the 4-level intermediate-band solar cell.

It is obvious that a solar cell may be appropriately designed by a combination of FIGS. 4 and 7 in such a manner that quantum dots composed of two different materials have different sizes.

The use of a plurality of quantum dot layers having different sizes and a plurality of different materials is more preferred. The reason for this is described below. The same reason is true for a 5-level intermediate-band solar cell and a 6-level intermediate-band solar cell.

A first reason is that impurity doping can be more effectively performed. That is, doping allows carriers to enter intermediate bands or localized levels. In the case of a large number of energy levels in one quantum-well potential (a potential formed by a quantum dot and a barrier layer), the number of carriers can become imbalanced in the energy levels during the operation of a solar cell. In contrast, in the case of a small number of levels, a more balanced state with respect to the number of carriers can be maintained in the energy levels during the operation of a solar cell, thereby allowing optical transitions to occur more effectively.

A second reason is that an energy relaxation time can be increased. It is reported that if a plurality of energy levels are present in one quantum-well potential, energy relaxation is suppressed by a phonon bottleneck effect (H. Benisty, C. M. Sotomayor-Torres and C. Weisbuch, Phys. Rev. B: Condens. Matter, 1991, 44, 10945). However, a smaller number of energy levels formed in one quantum-well potential may result in the suppression of carrier energy relaxation to increase the energy relaxation time, thereby allowing optical transitions to occur more effectively.

For the two reasons described above, a smaller number of energy levels formed from one quantum dot is more preferred. It is still more preferable that one energy level is formed from one quantum dot.

A 6-level intermediate-band solar cell which exhibits a schematic band diagram illustrated in FIG. 3 will be described below, the solar cell including four intermediate energy levels between the valence band of the barrier layers 8 and the conduction band of the barrier layers 8.

FIG. 3 is a schematic band diagram of the superlattice semiconductor layer 10 taken along alternate long and short dashed line A-A in FIG. 1. Each of the quantum dots 7 has four quantum levels.

In the 6-level intermediate-band solar cell, upon letting the densities of states of the intermediate energy levels be Y₁, Y₂, Y₃, and Y₄, and letting Yₜₒₜₐₗ=(Y₁+Y₂+Y₃+Y₄), the doping concentration of an activated n-type dopant in the superlattice semiconductor layer 10 preferably satisfies 0.18≦doping concentration/total density of states≦1. In other words, the superlattice semiconductor layer 10 preferably has four intermediate energy levels, and the superlattice semiconductor layer 10 preferably contains the activated n-type dopant in an atomic concentration of 0.18 or more times and 1 or less times as large as the sum total of the densities of states of the intermediate energy levels. Such a configuration enables an appropriate number of electrons to be present in the quantum dot layers 6 and enables electrons in the valence band of the barrier layers 8 or the quantum dot layers 6 to be efficiently photoexcited to the conduction band of the barrier layers 8 via the intermediate energy levels, thereby improving the photoelectric conversion efficiency of the solar cell.

Furthermore, the doping concentration of the activated n-type dopant in the superlattice semiconductor layer 10 more preferably satisfies 0.2≦doping concentration/total density of states≦0.75.

Moreover, the superlattice semiconductor layer 10 preferably contains the activated n-type dopant in an atomic concentration of 0.5 times as large as the sum total of the densities of states of the intermediate energy levels.

The superlattice semiconductor layer 10 having the four intermediate energy levels may be formed by adjusting, for example, the size of the quantum dot layers 6 and the thickness of the quantum dot layers 6 serving as well layers of the superlattice structure. For example, the formation of quantum dot layers composed of InGaAs on barrier layers composed of AlGaInAs, quantum dot layers composed of InGaN on barrier layers composed of AlGaN, or quantum dot layers composed of InAsSb on barrier layers composed of AlSbAs enables four intermediate bands to be formed in the superlattice semiconductor layer 10. Thus, as illustrated in the schematic cross-sectional view of FIG. 1, the 6-level intermediate-band solar cell may be produced by repeatedly stacking the quantum dot layers 6 having the same size.

A 6-level intermediate-band solar cell may also be produced by alternately and repeatedly stacking quantum dot layers 6a and 6b having two different sizes as illustrated in the schematic cross-sectional view of FIG. 4. FIG. 6 is a schematic band diagram of a band structure of the superlattice semiconductor layer 10 taken along alternate long and short dashed line B-B in FIG. 4. Each of the quantum dots 7a and 7b has two intermediate energy levels. The sum total of the intermediate energy levels is four, thus resulting in the 6-level intermediate-band solar cell. The small-sized quantum dots 7a have a size of d_{d} in the z direction. The large-sized quantum dots 7b have a size of d_{c} in the z direction.

Furthermore, a 6-level intermediate-band solar cell may be produced by alternately and repeatedly stacking quantum dot layers 6c and 6d composed of two different materials (including the case of different mixed crystal ratios) as illustrated in the schematic cross-sectional view of FIG. 7. In FIG. 7, the quantum dots 7 have the same size in the z direction. FIG. 9 is a schematic band diagram of the superlattice semiconductor layer 10 taken along alternate long and short dashed line C-C in FIG. 7. Each of the quantum dots 7c and 7d has two intermediate energy levels. In this case, the total number of the intermediate energy levels is four, thus resulting in the 6-level intermediate-band solar cell.

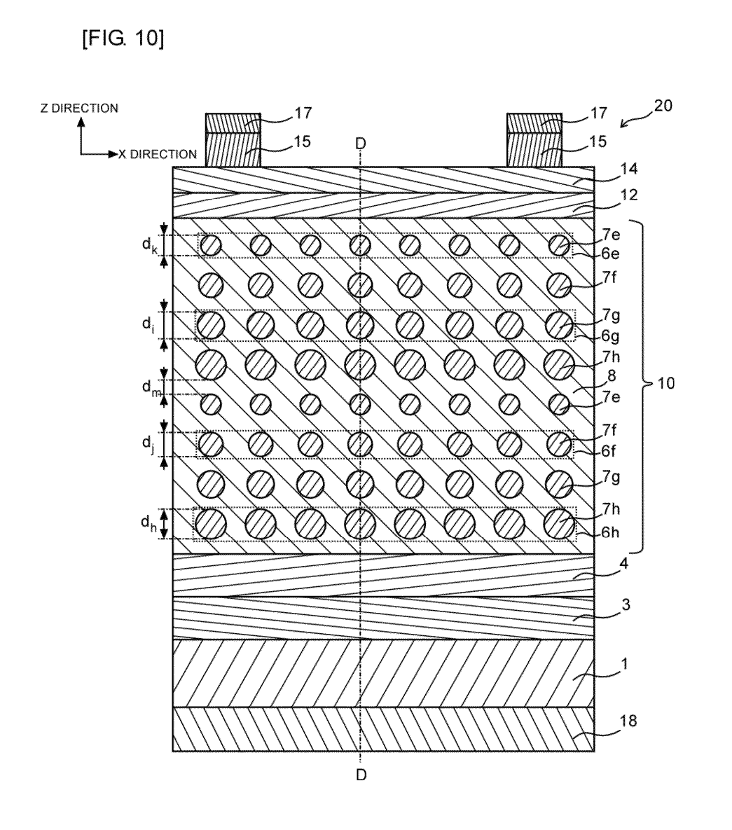

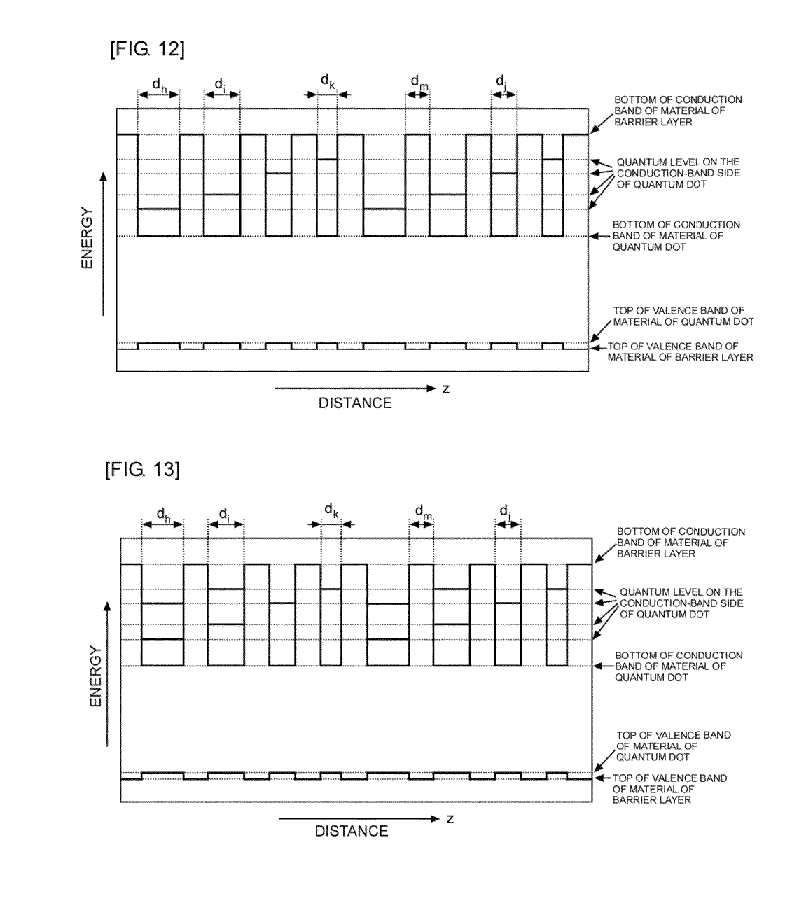

Furthermore, a 6-level intermediate-band solar cell may also be produced by periodically arranging quantum dot layers 6e, 6f, 6g, and 6h having four different sizes as illustrated in the schematic cross-sectional view of FIG. 10. In this case, FIGS. 12 and 13 illustrate schematic band structures when quantum dots having different sizes are used and are schematic band diagrams of the superlattice semiconductor layer 10 taken along alternate long and short dashed line D-D in FIG. 10. As illustrated in the band diagram of FIG. 12, the quantum dot layers 6e, 6f, 6g, and 6h contain quantum dots 7e, 7f, 7g, and 7h, respectively. These different quantum dots may have different intermediate energy levels, and the number of intermediate energy levels may be one for each quantum dot. In this case, the total number of the intermediate energy levels is four, thus resulting in the 6-level intermediate-band solar cell. Furthermore, as illustrated in the band diagram of FIG. 13, in the case where some of the quantum dots 7e, 7f, 7g, and 7h each have two intermediate energy levels and where the remaining quantum dots each have one intermediate energy level, a 6-level intermediate-band solar cell can also be produced.

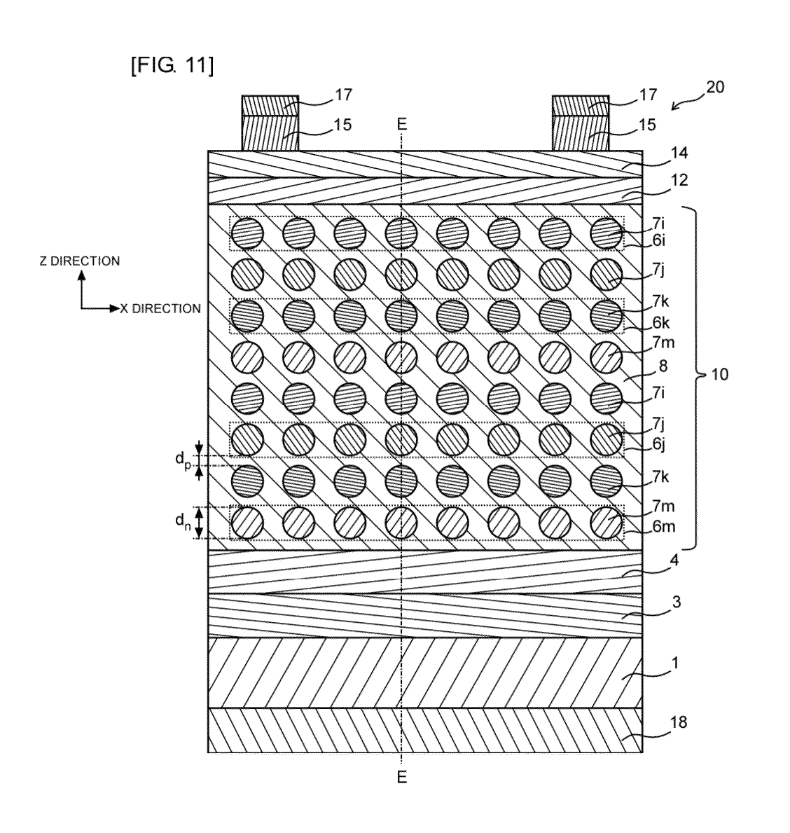

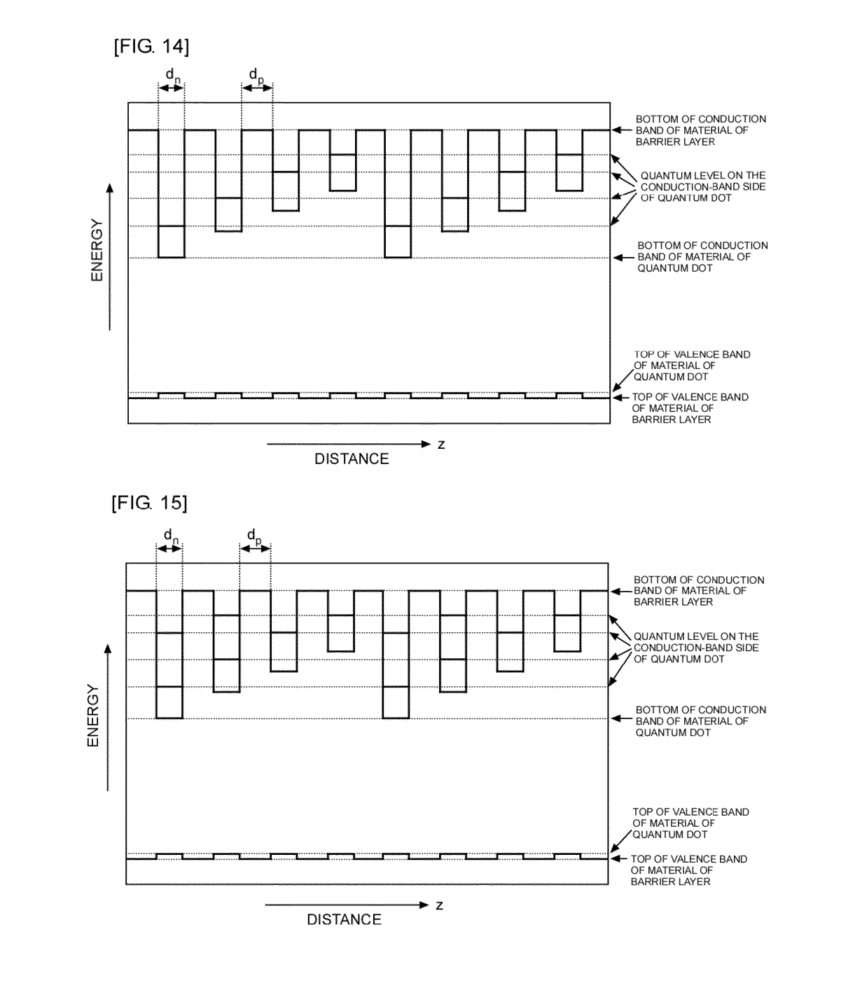

A 6-level intermediate-band solar cell may also be produced by periodically arranging quantum dot layers 6i, 6j, 6k, and 6m composed of four different materials as illustrated in the schematic cross-sectional view of FIG. 11. In this case, FIGS. 14 and 15 illustrate schematic band structures when quantum dots are composed of different materials and are schematic band diagrams of the superlattice semiconductor layer 10 taken along alternate long and short dashed line E-E in FIG. 11. As illustrated in the band diagram of FIG. 14, the quantum dot layers 6i, 6j, 6k, and 6m contain quantum dots 7i, 7j, 7k, and 7m, respectively. These different quantum dots may have different intermediate energy levels, and the number of intermediate energy levels may be one for each quantum dot. In this case, the total number of the intermediate energy levels is four, thus resulting in the 6-level intermediate-band solar cell. Furthermore, as illustrated in the band diagram of FIG. 15, in the case where some of the quantum dots 7i, 7j, 7k, and 7m each have two intermediate energy levels and where the remaining quantum dots each have one intermediate energy level, a 6-level intermediate-band solar cell can also be produced.

It is obvious that the materials and sizes of the quantum dots may be appropriately designed by a combination of FIGS. 7, 10, and 11.

In an intermediate-band solar cell having x intermediate bands or localized levels, in order to equalize electrons that enter quantum dots from an n-type doping, different dopants may be used, and x types of dopants may be used at a maximum. FIG. 16 is a band diagram corresponding to the band diagram of the superlattice semiconductor layer 10 taken along alternate long and short dashed line E-E in FIG. 11. The quantum dots 7i, 7j, 7k, and 7m each have one intermediate energy level and contain different types of n-type dopants. In this case, x=4. As described above, the selection of the dopants in response to the energy levels of the intermediate bands or localized levels in view of ionization energy may result in effective doping to allow optical transitions to occur efficiently. While the n-type dopants are incorporated into the barrier layers in FIG. 16, the quantum dots may be directly doped.

The barrier layers sandwiched between two adjacent quantum dot layers in the superlattice semiconductor layer 10 may include a plurality of types of barrier layers containing different types of n-type dopants. The plural types of barrier layers may contain different n-type dopants and may be periodically stacked.

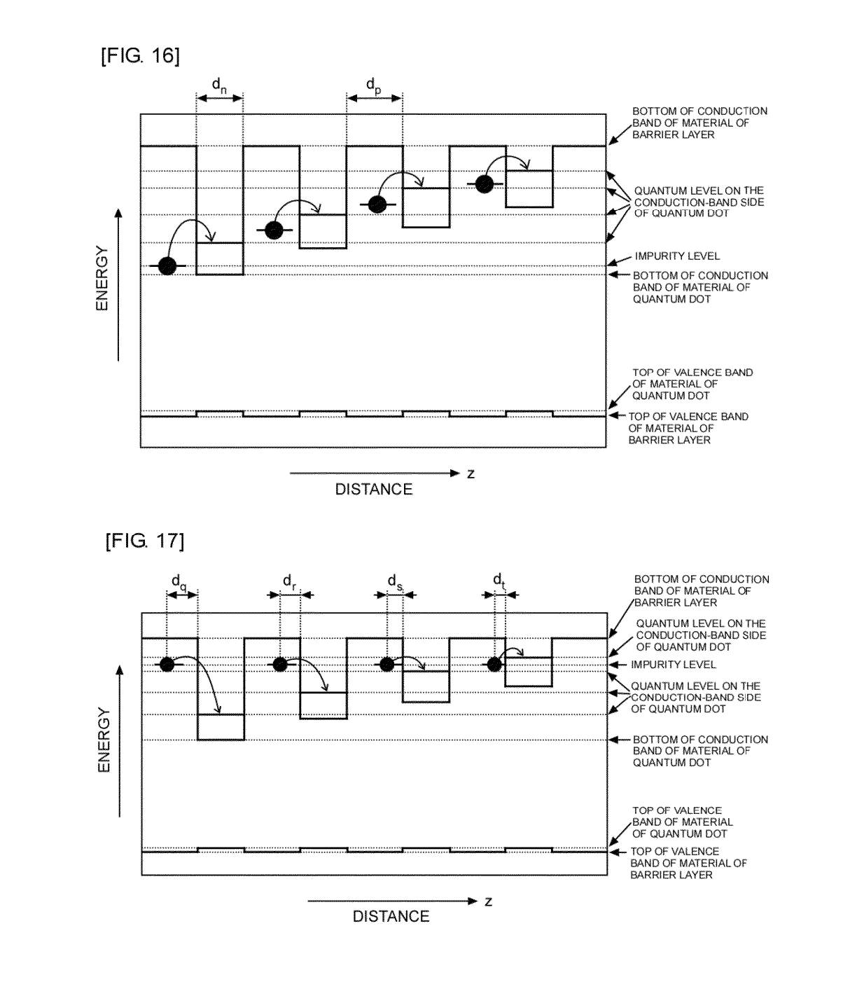

In an intermediate-band solar cell having x intermediate bands or localized levels, x types of quantum dot layers at a maximum may be used at different doping distances of one type of dopant in response to quantum energy levels. FIG. 17 is a band diagram corresponding to the band diagram of the superlattice semiconductor layer 10 taken along alternate long and short dashed line E-E in FIG. 11. The quantum dots 7i, 7j, 7k, and 7m each have one intermediate energy level and contain the same types of n-type dopant at different distances. In this case, x=4. The distances from edges of the barrier layers to the dopant satisfy d_{q}>dᵣ>dₛ>dₜ. As described above, the selection of the position of the dopant in response to the energy levels of the intermediate bands or localized levels in view of the activation rate results in effective doping to allow optical transitions to occur efficiently.

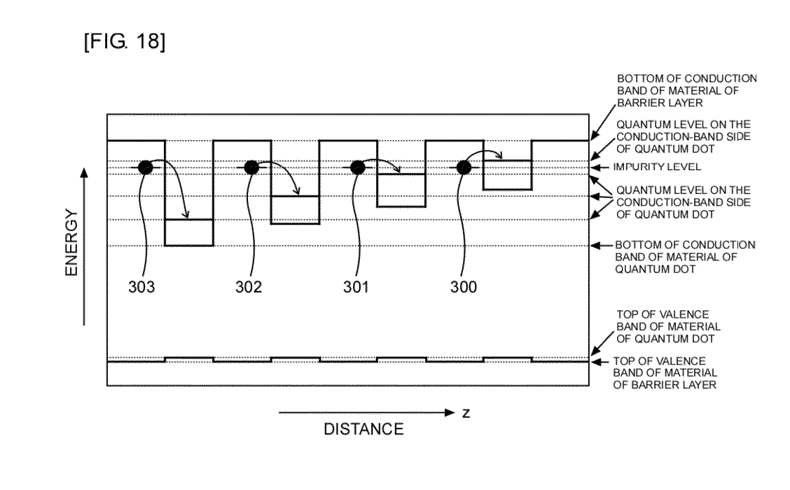

Alternatively, the proportion of the dopant may vary, depending on the energy levels, at the same distance from the edges of the barrier layers to the dopant. In FIG. 18, upon letting the proportions of the dopants 300 to 303 be r_{q}, rᵣ, rₛ, and rₜ, the proportions may satisfy r_{q}>rᵣ>rₛ>rₜ and r_{q}+rᵣ+rₛ+rₜ=1. As described above, the change in the proportion of the dopant in response to the energy levels of the intermediate bands or localized levels in view of the activation rate results in effective doping to allow optical transitions to occur efficiently.

Thereby, a balanced state with respect to the number of carriers can be maintained in the intermediate energy levels during the operation of the solar cell, thereby allowing optical transitions to occur more effectively.

While the 4-level intermediate-band solar cell and the 6-level intermediate-band solar cell have mainly been described above, a 5-level intermediate-band solar cell can also be produced in the same way as above.

### 3. Method for Producing Solar Cell

Regarding the quantum dot layers, the quantum dots may be produced by what is called a Stranski-Krastanov (S-K) growth method using a molecular beam epitaxy (MBE) method or a metal-organic chemical vapor deposition (MOCVD) method, an electron lithography technique, or a droplet epitaxy method. In the S-K growth method, the mixed crystal ratio of the quantum dots may be adjusted by changing the constituent ratio of the raw materials. The size of the quantum dots may be adjusted by changing the growth temperature, the pressure, the deposition time, and so forth.

Regarding the production of a solar cell according to this embodiment, a solar cell including a superlattice structure may be produced by, for example, a molecular beam epitaxy (MBE) method or a metal-organic chemical vapor deposition (MOCVD) method, which provide good thickness control. Here, regarding an embodiment of a solar cell including a superlattice structure as illustrated in FIG. 1 described above, a method for producing it will be described with reference to FIG. 1.

For example, a p-GaAs substrate (p-type semiconductor substrate) 1 is washed with an organic cleaning fluid, etched with a sulfuric acid-based etchant, washed in running water, and placed in an MOCVD apparatus. A buffer layer 3 is formed on the substrate. The buffer layer 3 is a layer to improve the crystallinity of a light absorption layer to be formed thereon. For example, a GaAs layer is formed. Subsequently, the p-type GaAs base layer (p-type semiconductor layer) 4 having a thickness of 300 nm and a GaAs layer serving as the barrier layer 8 are formed by crystal growth on the buffer layer 3. Then the quantum dot layer 6 composed of InAs is formed by a self-organizing mechanism. At this time, by appropriately changing the deposition time, the temperature, the pressure, the feed rate of raw materials, the constituent ratio of the raw materials, and so forth, the size and the composition of the quantum dots may be adjusted to desired values, and quantum wells may be formed.

The crystal growth operations of the barrier layer 8 and the quantum dot layer 6 are repeated from the quantum dot layer 6 closest to the p-type semiconductor layer 4 to a quantum dot layer closest to the n-type semiconductor layer 12. Here, in the case where n-type quantum dot layers are formed, for example, the quantum dot layers 6 are formed by crystal growth while introducing silane (SiH₄), thereby incorporating Si into the barrier layers 8. Si may be directly incorporated into the quantum dots 7.

Thereafter, the n-type GaAs layer (n-type semiconductor layer) 12 having a thickness of 250 nm is formed by crystal growth. Then an AlAs layer is formed as a window layer 14.

Subsequently, the n-type electrode 17 is formed on the contact layer 15 by a photolithography technique, a lift-off technique, and an etching technique, thereby producing the solar cell having the superlattice structure.

For example, Si may be used as an n-type dopant, and Zn may be used as a p-type dopant. Examples of another n-type dopant include S, Se, Sn, Te, and C. For example, Au may be used as an electrode material. The electrode may be formed by vacuum deposition using a resistance heating deposition method.

A solar cell including quantum dots composed of InAsSb and barrier layers composed of AlSb may be similarly produced. In the case of these materials, the use of a GaSb substrate reduces a lattice mismatch, which is more preferred.

The concentration of the n-type dopant in the superlattice semiconductor layer 10 may be determined by a secondary ion mass spectrometer (SIMS).

The density of states in the superlattice structure of the intermediate-band solar cell 20 may be determined by photoelectron spectroscopy (PES), ultraviolet photoelectron spectroscopy (UPS), X-ray photoelectron spectroscopy (XPS), and so forth. In the case of the superlattice structure including the quantum dots, the density of the quantum dots may be determined by transmission electron microscope (TEM) observation, the number of energy levels may be determined by photoluminescence (PL) measurement described below, and then the density of states may be calculated.

The emission spectrum of the resulting solar cell may be measured by photoluminescence (PL) measurement to determine, for example, the number of intermediate bands or localized levels. For example, the photoluminescence of the superlattice semiconductor layer 10 is measured at 11 K with an Ar laser serving as an excitation light source and a Ge photodetector serving as a detector. Levels at which the intermediate bands or localized levels are formed may be determined by determining energy (photon energy) corresponding to the emission band of the measured emission spectrum. Furthermore, the band gap of the barrier layers 8 may be determined. An optical absorption spectrum may be measured to check the formation of the intermediate bands.

The embodiment described here is merely an example. The materials for the substrate, the barrier layers, the quantum dots, the dopants, the electrodes, and so forth used for the solar cell having the superlattice structure according to this embodiment and the cleaning agent, the temperature for processing the substrate, the production apparatuses, and so forth used in the respective processes are not limited to those described above.

### 4. Simulation Experiment

### [Experiment 1]

A simulation experiment was performed on the structure of a 4-level intermediate-band solar cell. As with a technique commonly used for the analysis of semiconductor devices, the simulation was performed by self-consistently solving an equation that indicates that an intermediate band or a localized level is separated from an electrode and that no carrier is taken from the intermediate level to the electrode in addition to Poisson's equation, the electron continuity equation, and the hole continuity equation. The energy conversion efficiencies were calculated and compared, provided that only the dopant concentration was changed and that the remaining conditions were unchanged. In this experiment, the material of the quantum dots was InAs_{0.7}Sb_{0.3}, and the material of the barrier layers was AlSb. The use of these materials enables the band offset of the valence band to be set to substantially zero.

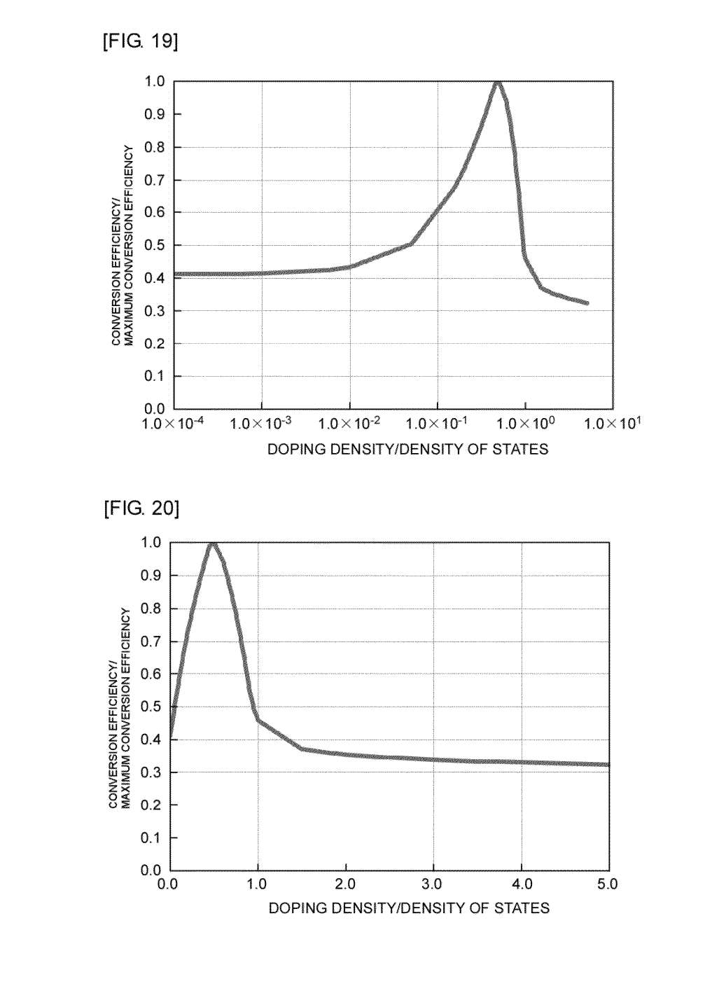

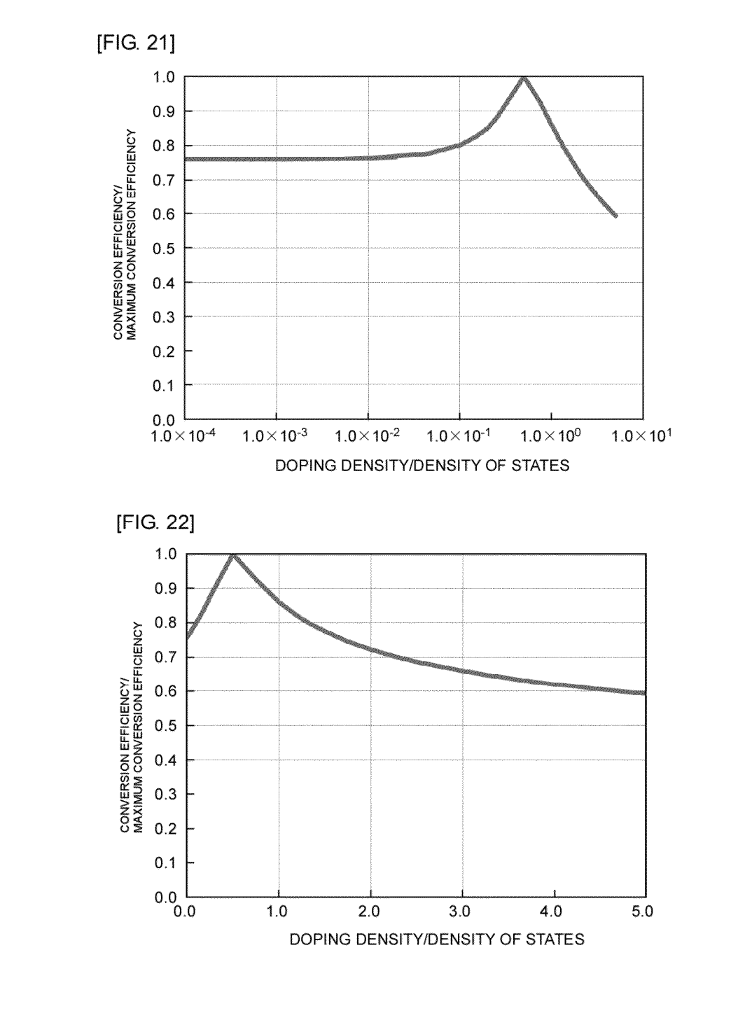

FIGS. 19 and 20 illustrate the relationship between activated dopant concentration/total density of states and energy conversion efficiency/maximum energy conversion efficiency under no concentration conditions. FIGS. 21 and 22 illustrate the results under 1000 suns concentration conditions. FIGS. 19 and 21 are logarithmic graphs. FIGS. 20 and 22 are linear graphs.

These results demonstrate that when the doping concentration is more than half the density of states, the energy conversion efficiency is markedly reduced. The reason for this is that an excessively high doping concentration allows the intermediate bands to be filled with electrons, so that optical transitions from the valence band to the intermediate bands does not easily occur. It is also found that a reduction in energy conversion efficiency is suppressed in a wide range of the doping concentration under sun concentration. The reason for this is presumably that when the presence of a sufficiently large number of photons allows the optical transitions to occur rapidly, so that the energy conversion efficiency is less likely to be affected by the doping concentration.

The solar cell is believed to be practical when the energy conversion efficiency is at least 80% or more of the maximum energy conversion efficiency (that is, in FIGS. 18 and 19, the value of “energy conversion efficiency/maximum energy conversion efficiency” is 0.8 or more).

Thus, at least, preferably, 0.1≦doping concentration/total density of states≦1.5, and more preferably, 0.25≦doping concentration/total density of states≦0.75.

Furthermore, carriers are preferably present in substantially the same concentration for each intermediate band or localized level during the operation of the solar cell in view of optical transitions.

### [Experiment 2]

A simulation experiment was performed on the structure of a 5-level intermediate-band solar cell. The energy conversion efficiencies were calculated and compared, provided that only the dopant concentration was changed. In this experiment, the material of the quantum dots was InAs_{0.7}Sb_{0.3}, and the material of the barrier layers was AlSb.

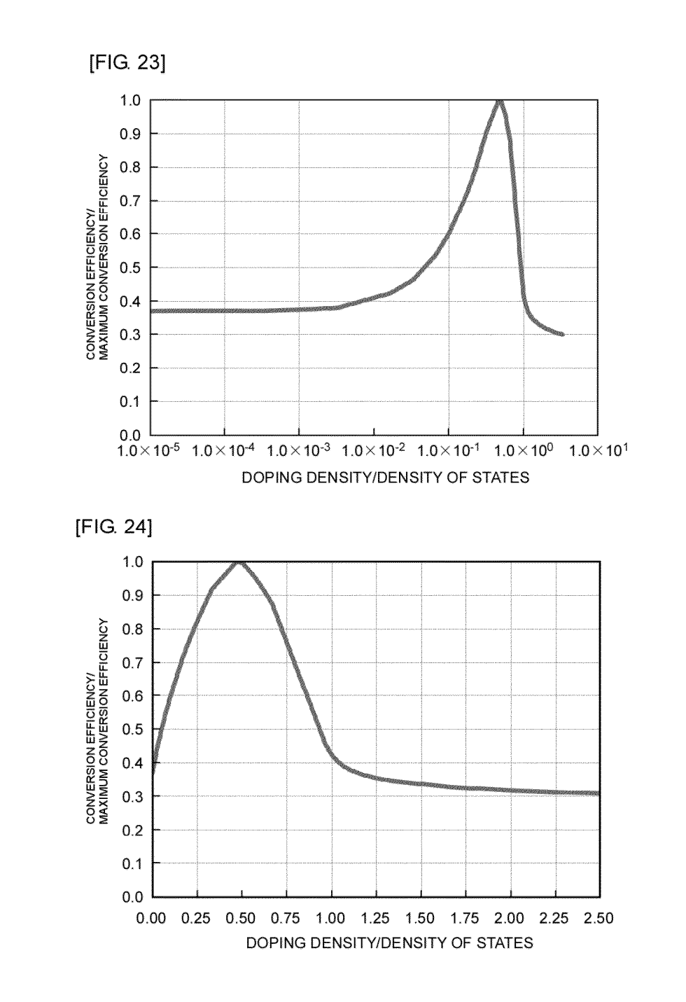

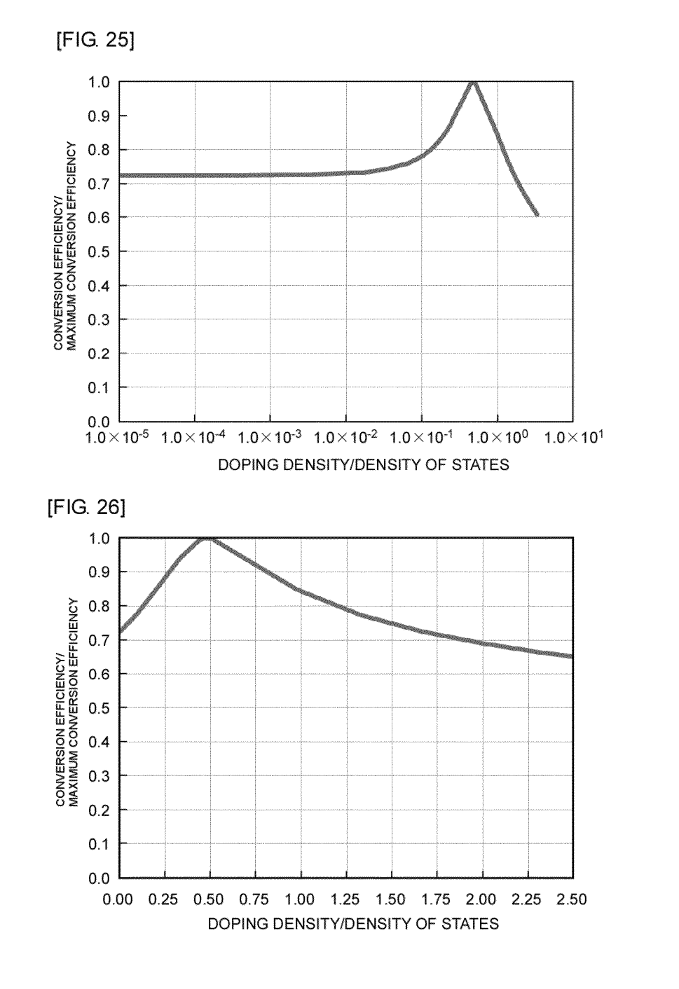

FIGS. 23 and 24 illustrate the relationship between activated dopant concentration/density of energy states and energy conversion efficiency/maximum energy conversion efficiency under no concentration conditions. FIGS. 25 and 26 illustrate the results under 1000 suns concentration conditions. FIGS. 23 and 25 are logarithmic graphs. FIGS. 24 and 26 are linear graphs.

The solar cell is practical when the energy conversion efficiency is at least 80% or more of the maximum energy conversion efficiency (that is, in FIGS. 23 to 26, the value of “energy conversion efficiency/maximum energy conversion efficiency” is 0.8 or more).

Thus, at least, preferably, 0.13≦doping concentration/total density of states≦1.20, and more preferably, 0.25≦doping concentration/total density of states≦0.70.

Furthermore, carriers are preferably present in substantially the same concentration for each intermediate band or localized level during the operation of the solar cell in view of optical transitions.

### [Experiment 3]

A simulation experiment was performed on the structure of a 6-level intermediate-band solar cell. The energy conversion efficiencies were calculated and compared, provided that only the dopant concentration was changed. In this experiment, the material of the quantum dots was InAs_{0.7}Sb_{0.3}, and the material of the barrier layers was AlSb.

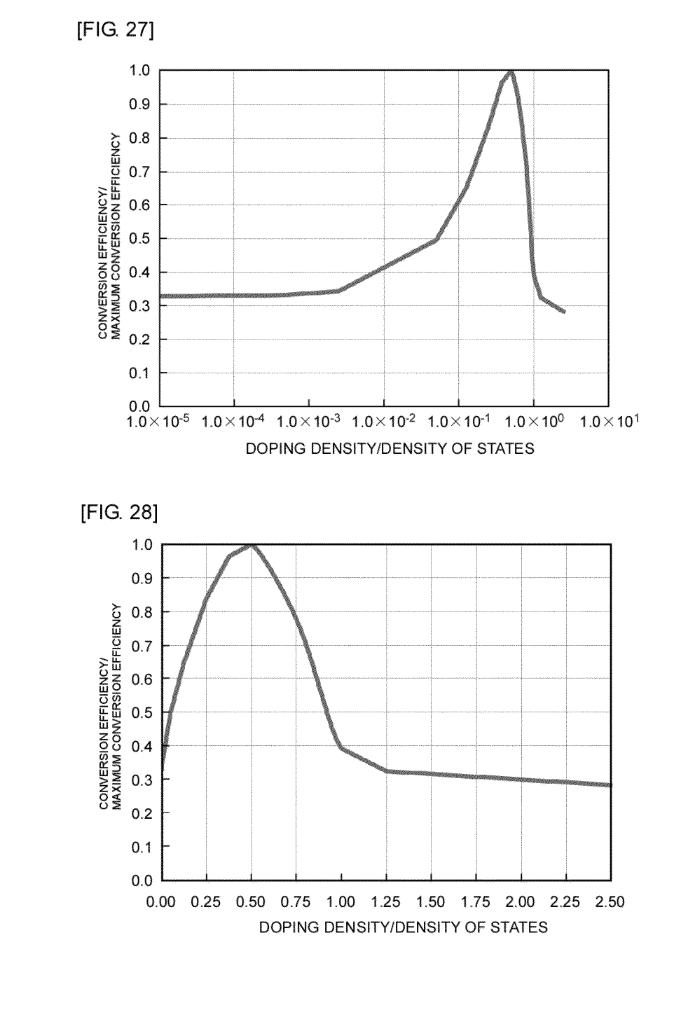

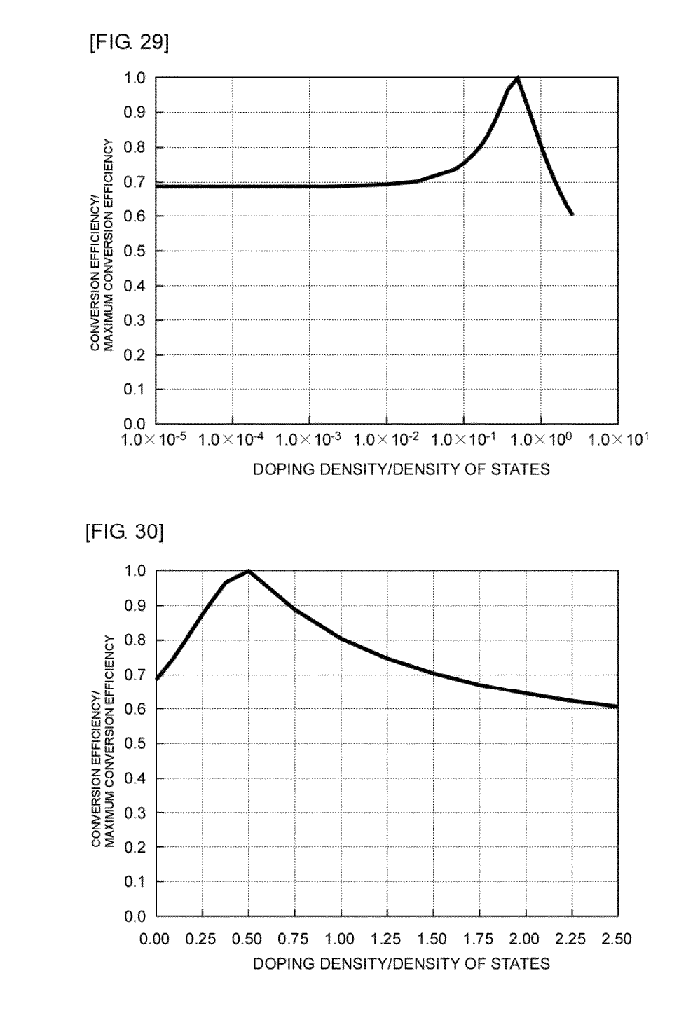

FIGS. 27 and 28 illustrate the relationship between activated dopant concentration/total density of states and energy conversion efficiency/maximum energy conversion efficiency under no concentration conditions. FIGS. 29 and 30 illustrate the results under 1000 suns concentration conditions. FIGS. 27 and 29 are logarithmic graphs. FIGS. 28 and 30 are linear graphs.

The solar cell is practical when the energy conversion efficiency is at least 80% or more of the maximum energy conversion efficiency (that is, in FIGS. 27 to 30, the value of “energy conversion efficiency/maximum energy conversion efficiency” is 0.8 or more).

Thus, at least, preferably, 0.18≦doping concentration/total density of states≦1, and more preferably, 0.2≦doping concentration/total density of states≦0.75.

Furthermore, carriers are preferably present in substantially the same concentration for each intermediate band or localized level during the operation of the solar cell in view of optical transitions.

### [Experiment 4]

A simulation experiment was performed on the structure of a 4-level intermediate-band solar cell. The energy conversion efficiencies were calculated and compared, provided that only the dopant concentration was changed. In this experiment, the material of the quantum dots was InAs, and the material of the barrier layers was GaAs.

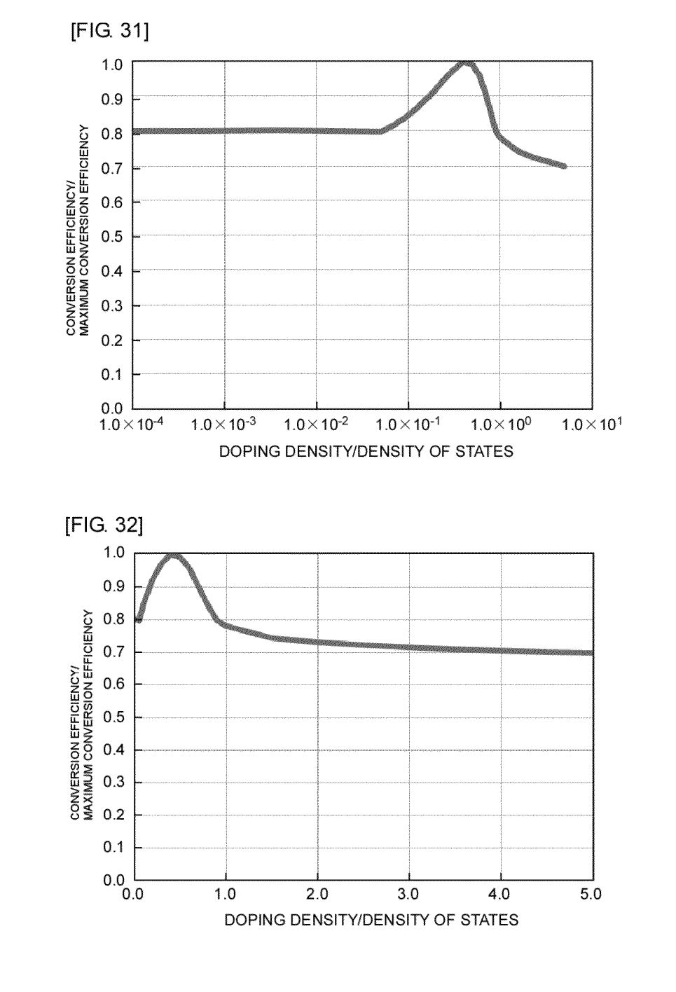

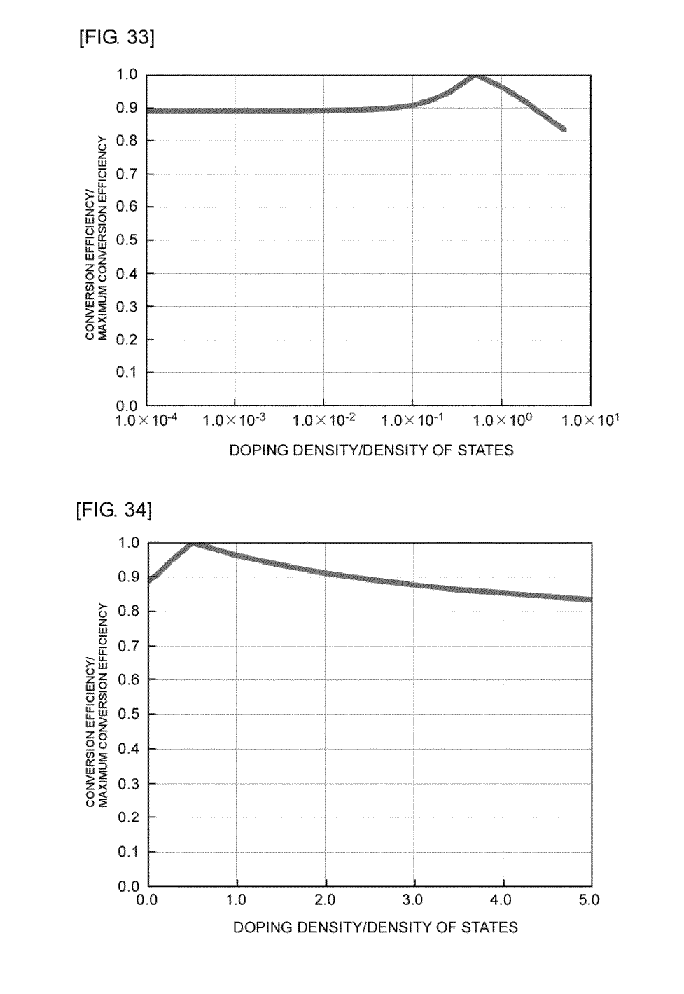

FIGS. 31 and 32 illustrate the relationship between activated dopant concentration/total density of states and energy conversion efficiency/maximum energy conversion efficiency under no concentration conditions. FIGS. 33 and 34 illustrate the results under 1000 suns concentration conditions. FIGS. 31 and 33 are logarithmic graphs. FIGS. 32 and 34 are linear graphs.

The solar cell is practical when the energy conversion efficiency is at least 80% or more of the maximum energy conversion efficiency (that is, in FIGS. 27 to 30, the value of “energy conversion efficiency/maximum energy conversion efficiency” is 0.8 or more).

Thus, at least, preferably, 0.03≦doping concentration/total density of states≦3.0, and more preferably, 0.05≦doping concentration/total density of states≦1.0.

Furthermore, carriers are preferably present in substantially the same concentration for each intermediate band or localized level during the operation of the solar cell in view of optical transitions.

### [Experiment 5]

A simulation experiment was performed on the structure of a 5-level intermediate-band solar cell. The energy conversion efficiencies were calculated and compared, provided that only the dopant concentration was changed. In this experiment, the material of the quantum dots was InAs, and the material of the barrier layers was GaAs.

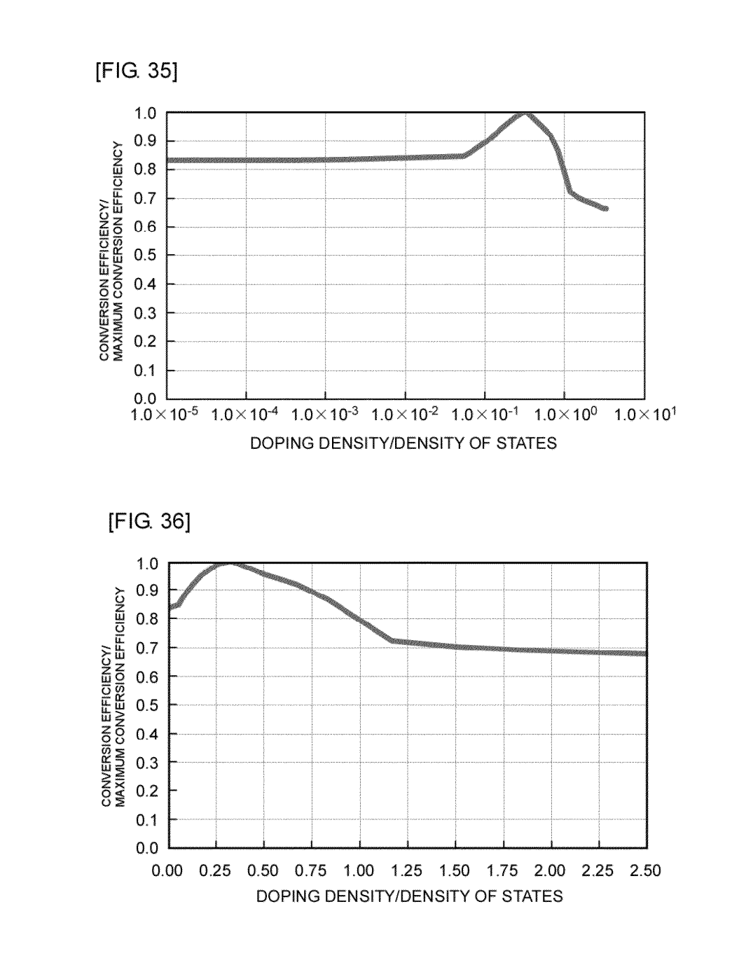

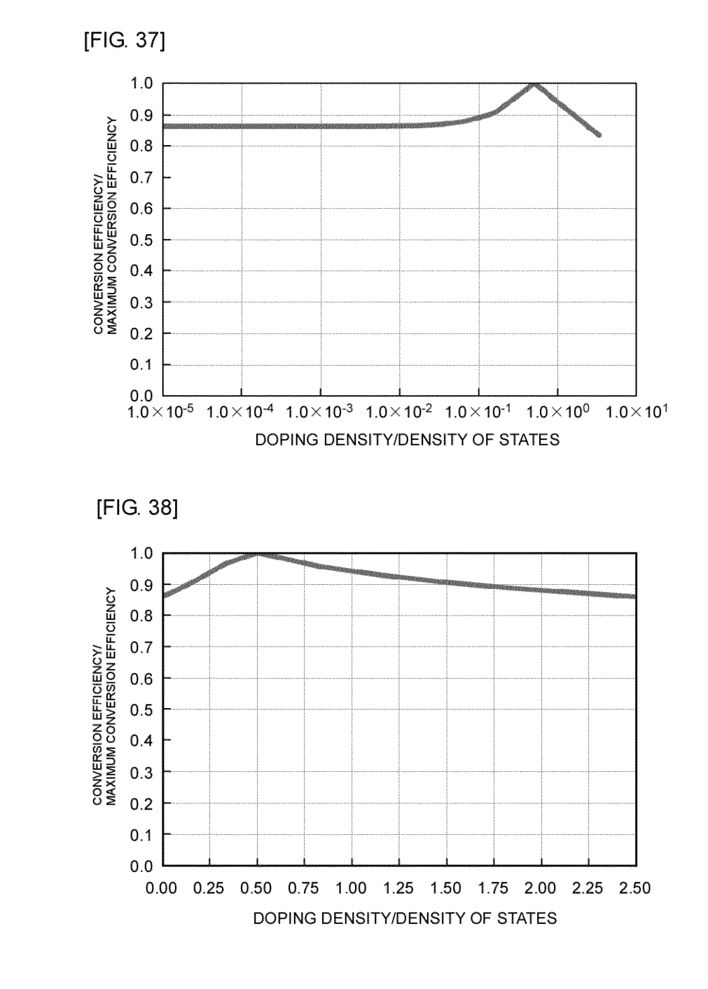

FIGS. 35 and 36 illustrate the relationship between activated dopant concentration/density of energy states and energy conversion efficiency/maximum energy conversion efficiency under no concentration conditions. FIGS. 37 and 38 illustrate the results under 1000 suns concentration conditions. FIGS. 35 and 37 are logarithmic graphs. FIGS. 36 and 38 are linear graphs.

The solar cell is practical when the energy conversion efficiency is at least 80% or more of the maximum energy conversion efficiency (that is, in FIGS. 23 to 26, the value of “energy conversion efficiency/maximum energy conversion efficiency” is 0.8 or more).

Thus, at least, preferably, 1.0×10⁻⁵≦doping concentration/total density of states≦2.5, and more preferably, 1.0×10⁻⁵≦doping concentration/total density of states≦1.0.

Furthermore, carriers are preferably present in substantially the same concentration for each intermediate band or localized level during the operation of the solar cell in view of optical transitions.

### [Experiment 6]

A simulation experiment was performed on the structure of a 6-level intermediate-band solar cell. The energy conversion efficiencies were calculated and compared, provided that only the dopant concentration was changed. In this experiment, the material of the quantum dots was InAs, and the material of the barrier layers was GaAs.

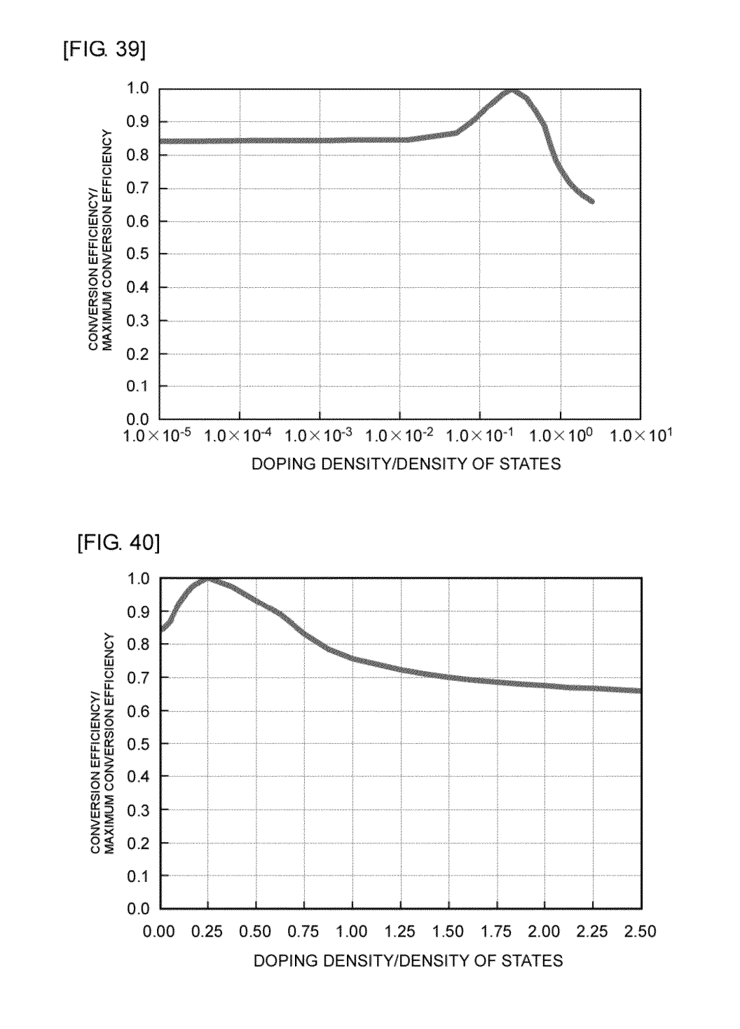

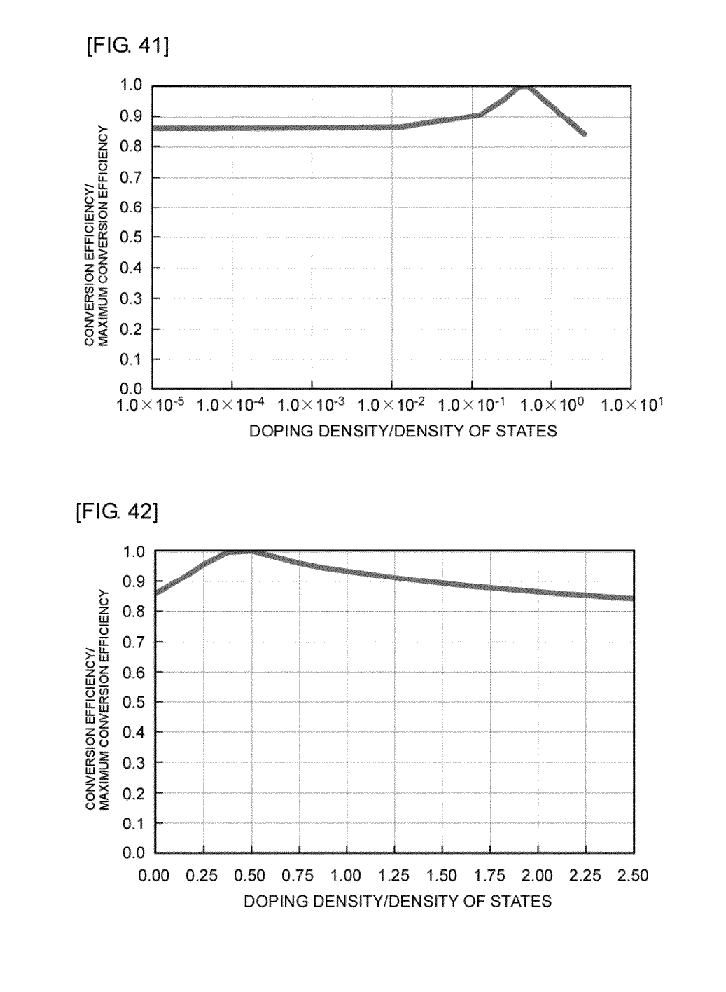

FIGS. 39 and 40 illustrate the relationship between activated dopant concentration/density of energy states and energy conversion efficiency/maximum energy conversion efficiency under no concentration conditions. FIGS. 41 and 42 illustrate the results under 1000 suns concentration conditions. FIGS. 39 and 41 are logarithmic graphs. FIGS. 40 and 42 are linear graphs.

The solar cell is practical when the energy conversion efficiency is at least 80% or more of the maximum energy conversion efficiency (that is, in FIGS. 27 to 30, the value of “energy conversion efficiency/maximum energy conversion efficiency” is 0.8 or more).

Thus, at least, preferably, 1.0×10⁻⁵≦doping concentration/total density of states≦2.5, and more preferably, 1.0×10⁻⁵≦doping concentration/total density of states≦0.8.

Furthermore, carriers are preferably present in substantially the same concentration for each intermediate band or localized level during the operation of the solar cell in view of optical transitions.

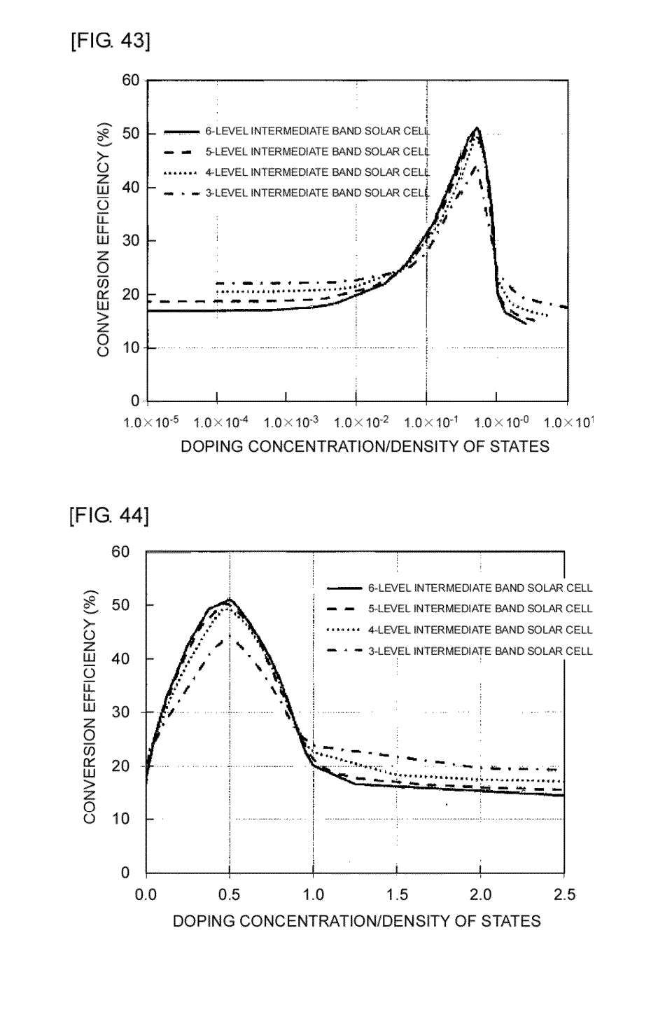

FIGS. 43 to 50 illustrate the results of comparisons of the conversion efficiencies obtained by Experiments 1 to 6 on the same graph. Furthermore, the conversion efficiency of a 3-level intermediate-band solar cell was calculated as a comparative example in addition to the calculations for the 4- to 6-level intermediate-band solar cells.

FIGS. 43 and 44 illustrate the results of Experiments 1 to 3 under no concentration conditions together with the results of the 3-level intermediate-band solar cell as the comparative example. As is apparent from the results, in the case where the material of the quantum dots is InAs_{0.7}Sb_{0.3} and where the material of the barrier layers is AlSb, when the “doping concentration/density of states” is in the vicinity of 0.5, the 4- to 6-level intermediate-band solar cells have larger conversion efficiencies than the 3-level intermediate-band solar cell. However, when the “doping concentration/density of states” is markedly away from 0.5, the 3-level intermediate-band solar cell has larger conversion efficiency than the 4- to 6-level intermediate-band solar cells. This indicates that in the 4- to 6-level intermediate-band solar cells, recombination can be dominant rather than carrier formation at an inappropriate doping concentration. When the “doping concentration/density of states” is in the vicinity of about 0.5, the conversion efficiencies of the 4- to 6-level intermediate-band solar cells are maximized, and the difference in conversion efficiency between the 4- to 6-level intermediate-band solar cells and the 3-level intermediate-band solar cell is also maximized.

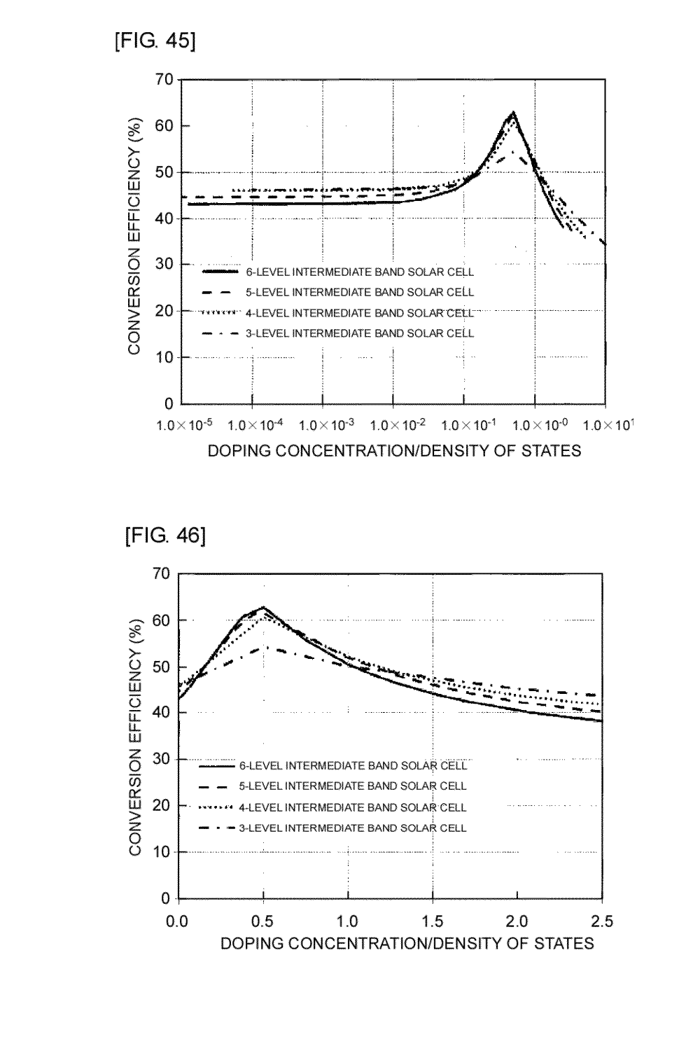

FIGS. 45 and 46 illustrate the results of Experiments 1 to 3 under 1000 suns concentration conditions together with the results of the 3-level intermediate-band solar cell as the comparative example. While the values of the conversion efficiencies are, of course, different, they have the same tendency as those under the no-light collection conditions. When the “doping concentration/density of states” is in the vicinity of about 0.5, the conversion efficiencies of the 4- to 6-level intermediate-band solar cells are maximized, and the difference in conversion efficiency between the 4- to 6-level intermediate-band solar cells and the 3-level intermediate-band solar cell is also maximized.

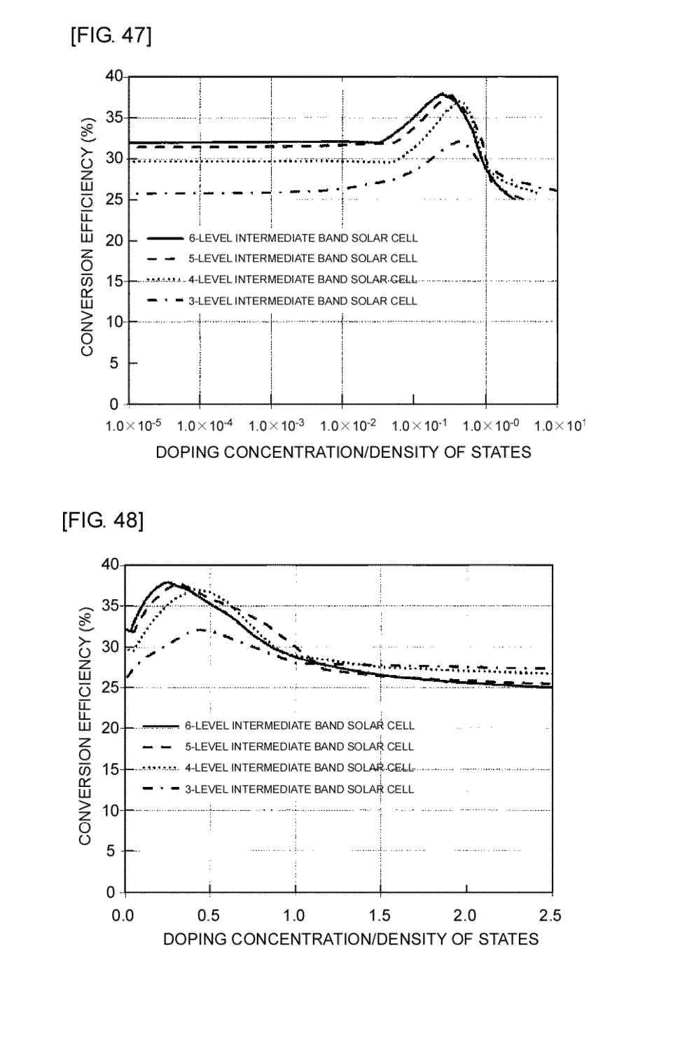

FIGS. 47 and 48 illustrate the results of Experiments 4 to 6 under no concentration conditions together with the results of the 3-level intermediate-band solar cell as the comparative example. As is apparent from the results, in the case where the material of the quantum dots is InAs and where the material of the barrier layers is AlSb, when the “doping concentration/density of states” is about 1.0 or less, the 4- to 6-level intermediate-band solar cells have larger conversion efficiencies than the 3-level intermediate-band solar cell. However, when the “doping concentration/density of states” is more than 1.0, the 3-level intermediate-band solar cell has larger conversion efficiency than the 4- to 6-level intermediate-band solar cells. When the “doping concentration/density of states” is in the vicinity of about 0.25 to about 0.5, the conversion efficiencies of the 4- to 6-level intermediate-band solar cells are maximized.

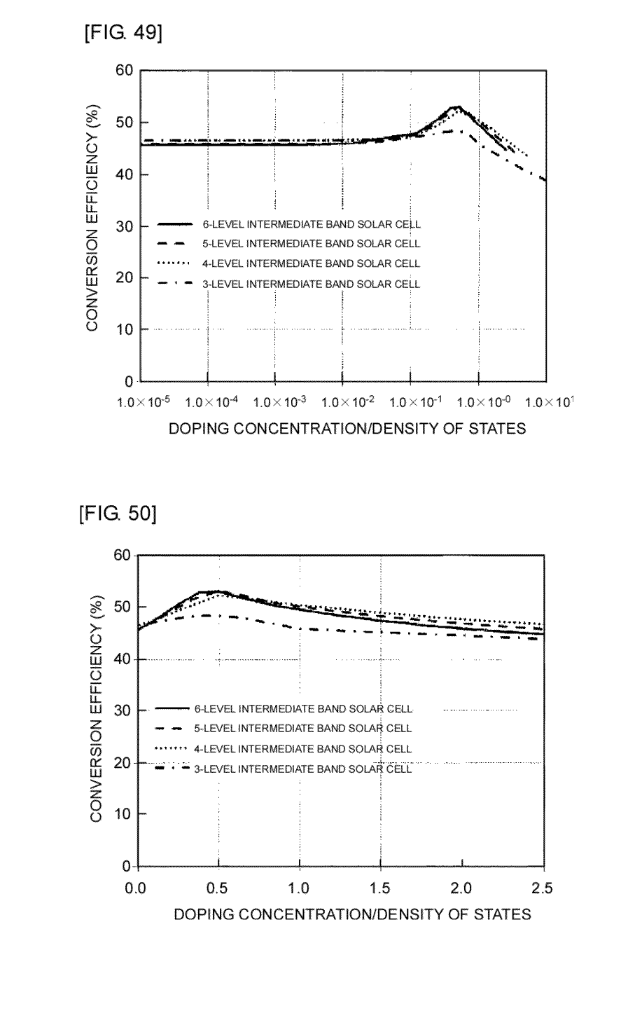

FIGS. 49 and 50 illustrate the results of Experiments 4 to 6 under 1000 suns concentration conditions together with the results of the 3-level intermediate-band solar cell as the comparative example. In this case, the 4- to 6-level intermediate-band solar cells have conversion efficiencies comparable to or larger than the 3-level intermediate-band solar cell throughout the range of the “doping concentration/density of states”. When the “doping concentration/density of states” is in the vicinity of about 0.5, the conversion efficiencies of the 4- to 6-level intermediate-band solar cells are maximized, and the difference in conversion efficiency between the 4- to 6-level intermediate-band solar cells and the 3-level intermediate-band solar cell is also maximized.

While the present invention has been described above with reference to the embodiments, the present invention is not limited to the embodiments.

In the foregoing embodiments, the superlattice structures mainly formed of the quantum dots and the quantum wells have been described. However, for example, the present invention may also be applied to a highly mismatched material and so forth. The present invention is not limited to intermediate-band solar cells having superlattice structures.

Various modifications can be made to the present invention within the scope defined by the claims. Thus, the technical scope of the present invention also encompasses embodiments achieved by combining technical means appropriately modified within the scope defined by the claims.

### REFERENCE SIGNS LIST

1 p-type semiconductor substrate; 3 barrier layer; 4 base layer (p-type semiconductor layer); 6, 6a to 6k, 6m quantum dot layer; 7, 7a to 7k, 7m quantum dot; 8 barrier layer; 10 superlattice semiconductor layer; 12 emitter layer (n-type semiconductor layer); 14 window layer; 15 contact layer; 17 n-type electrode; 18 p-type electrode; 20 solar cell

1. A solar cell comprising a p-type semiconductor layer, an n-type semiconductor layer, and a superlattice semiconductor layer interposed between the p-type semiconductor layer and the n-type semiconductor layer,
wherein the superlattice semiconductor layer has a superlattice structure in which barrier layers and quantum dot layers each including a plurality of quantum dots are stacked alternately and repeatedly, the superlattice semiconductor layer contains an n-type dopant and has at least two intermediate energy levels at which electrons photoexcited from the valence band of the quantum dots or the barrier layers can be present for a certain period of time, each of the intermediate energy levels is located between the top of the valence band of the barrier layers and the bottom of the conduction band of the barrier layers,
each of the intermediate energy levels is formed from one or a plurality of quantum levels of the quantum dots, and
the superlattice semiconductor layer contains an activated n-type dopant.

2. The solar cell according to claim 1, wherein the superlattice semiconductor layer contains the activated n-type dopant in an atomic concentration of 0.1 or more times and 1.5 or less times as large as the sum total of the densities of states of the intermediate energy levels.

3. The solar cell according to claim 1 or 2, wherein the number of the intermediate energy levels in the superlattice semiconductor layer is two or more, and the superlattice semiconductor layer contains the activated n-type dopant in an atomic concentration of 0.1 or more times and 1.5 or less times as large as the sum total of the densities of states of the intermediate energy levels.

4. The solar cell according to claim 1, wherein the number of the intermediate energy levels in the superlattice semiconductor layer is three or more, and the superlattice semiconductor layer contains the activated n-type dopant in an atomic concentration of 0.13 or more times and 1.20 or less times as large as the sum total of the densities of states of the intermediate energy levels.

5. The solar cell according to claim 1, wherein the number of the intermediate energy levels in the superlattice semiconductor layer is four or more, and the superlattice semiconductor layer contains the activated n-type dopant in an atomic concentration of 0.18 or more times and 1 or less times as large as the sum total of the densities of states of the intermediate energy levels.

6. The solar cell according to claim 1, wherein the quantum dots contained in one quantum dot layer have substantially the same size in a direction in which the barrier layers and the quantum dot layers are repeatedly stacked, and
the quantum dots contained in the quantum dot layers that are contained in the superlattice semiconductor layer have substantially the same size in the direction in which the barrier layers and the quantum dot layers are repeatedly stacked.

7. The solar cell according to claim 1, wherein the quantum dots contained in one quantum dot layer have substantially the same size in a direction in which the barrier layers and the quantum dot layers are repeatedly stacked,
the superlattice semiconductor layer has a structure in which a plurality of types of the quantum dot layers are periodically stacked, and
the quantum dots contained in the plurality of types of the quantum dot layers have different sizes in the direction in which the barrier layers and the quantum dot layers are repeatedly stacked.

8. The solar cell according to claim 1, wherein the quantum dots contained in one quantum dot layer are composed of the same material,
the superlattice semiconductor layer has a structure in which a plurality of types of the quantum dot layers are periodically stacked, and
the quantum dots contained in the plurality of types of the quantum dot layers are composed of different materials.

9. The solar cell according to claim 1, wherein the quantum dots contained in one quantum dot layer contain the same type of the n-type dopant,
the superlattice semiconductor layer has a structure in which a plurality of types of the quantum dot layers are periodically stacked, and
the quantum dots contained in the plurality of types of the quantum dot layers contain different types of the n-type dopants.

10. The solar cell according to claim 7, wherein upon letting the number of the intermediate energy levels in the superlattice semiconductor layer be x, the superlattice semiconductor layer has x types of the quantum dot layers.

11. The solar cell according to claim 6, wherein the number of the intermediate energy levels in the superlattice semiconductor layer is two, three, or four.

12. The solar cell according to claim 1, wherein the intermediate energy levels are intermediate bands or localized levels.

13. The solar cell according to claim 1, wherein the intermediate energy levels are formed from one or a plurality of quantum levels on the conduction-band side of the quantum dots.

14. The solar cell according to claim 1, wherein the barrier layers contains n-type dopants,
the superlattice semiconductor layer has a structure in which a plurality of types of the barrier layers are periodically stacked, and
the plurality of types of the barrier layers contain different types of the n-type dopants.
